(19) United States
(12) Patent Application Publication
(10) Pub. No.: US 2026/0314028 A1
(43) Pub. Date: Oct. 8, 2026

(54) METAL LAYER LAYOUT DESIGN FOR CIRCUIT CELLS IN HIGH-DENSITY SEMICONDUCTOR DEVICES

(71) Applicant: TAIWAN SEMICONDUCTOR MANUFACTURING COMPANY, LTD., Hsinchu (TW)

(72) Inventors: Li-Wei LU, Taichung City (TW); Yu-Cheng YEH, New Taipei City (TW); Yu-Lung TUNG, Kaohsiung City (TW); Shang-Hsuan CHIU, Hsinchu (TW); Jia-Hong GAO, Hsinchu County (TW)

(73) Assignee: TAIWAN SEMICONDUCTOR MANUFACTURING COMPANY, LTD., Hsinchu (TW)

(21) Appl. No.: 19/171,481

(22) Filed: Apr. 7, 2025

(51) Int. Cl. H10D 84/01; H01L 23/528

(52) U.S. Cl. CPC H10D 84/0149; H10W 20/43

(57) ABSTRACT

The present disclosure provides a method to address the inefficiency in Metal-0 (M0) layout design for one-half-height (OHH) cells. Specifically, the width of M0 tracks can be increased, and thus the size of the via associated with the M0 layer can be expanded to reduce resistance (Rc). Additionally, a functionless M0 track can be removed. Furthermore, no additional mask is required for implementing this new layout. Therefore, these improvements can collectively enhance the electrical performance of the OHH cells by reducing Rc and enabling faster operational speeds.

### BACKGROUND

Semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing are needed.

In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling-down also produces a relatively high power dissipation value, which may be addressed by using low power dissipation devices such as complementary metal-oxide-semiconductor (CMOS) devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a fragmentary diagrammatic top view of an integrated circuit (IC) chip, in portion or entirety, in accordance with some embodiments of the present disclosure.

FIG. 1B illustrates a layout diagram in accordance with some embodiments of the present disclosure.

FIG. 1C is a local enlarged view of the semiconductor structure according to a region C1 in FIG. 1B.

FIGS. 1D-1F illustrate semiconductor structures corresponding to FIG. 1C in accordance with some embodiments of the present disclosure.

FIG. 1G illustrates a fragmentary diagrammatic top view (or layout) of a semiconductor structure in a region (e.g., logic region) of an IC chip, in accordance with some embodiments of the present disclosure.

FIG. 2 is a perspective view of a GAA transistor in the array of circuit cells, in accordance with some embodiments of the present disclosure.

FIGS. 3A-3C illustrate cross-sectional views obtained from reference cross-sections C1-C1′, C2-C2′, and C3-C3′, respectively, in FIG. 2, in accordance with some embodiments of the present disclosure.

FIG. 4-10C illustrate schematic views of intermediate stages in the formation of a semiconductor structure in accordance with some embodiments.

FIG. 11A is a schematic diagram of an electronic design automation (EDA) system in accordance with some embodiments of the present disclosure.

FIG. 11B is a block diagram of an IC manufacturing system and an IC manufacturing flow associated therewith, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

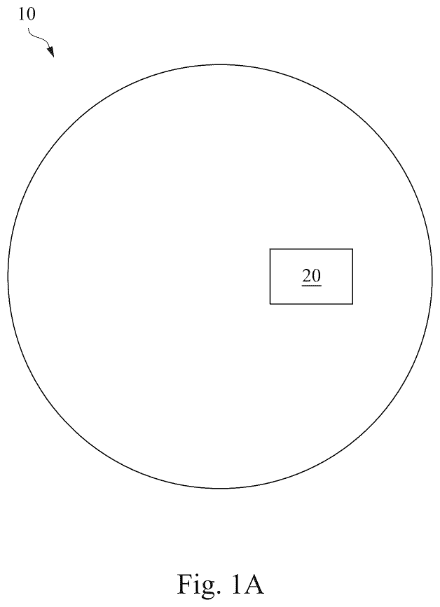

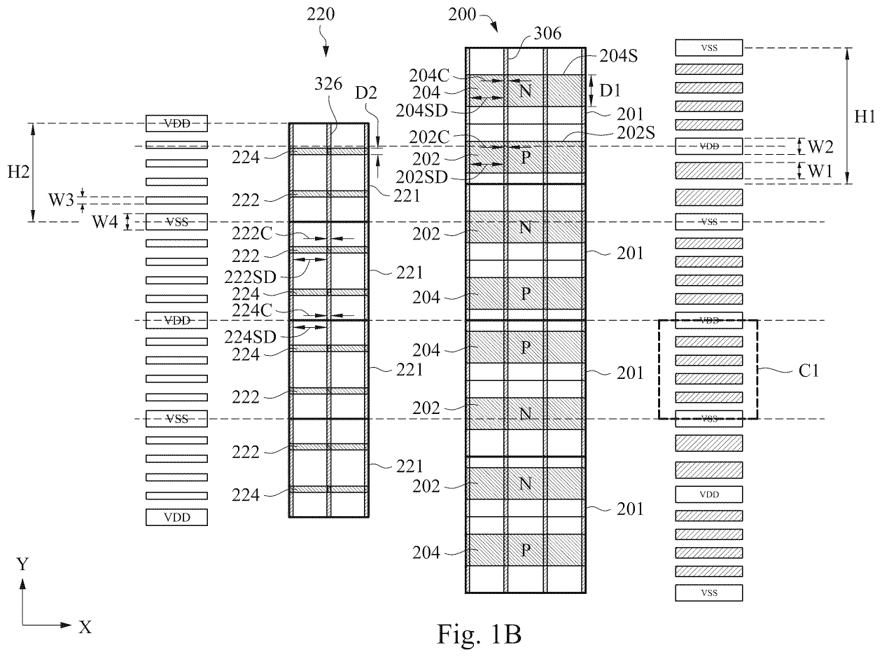

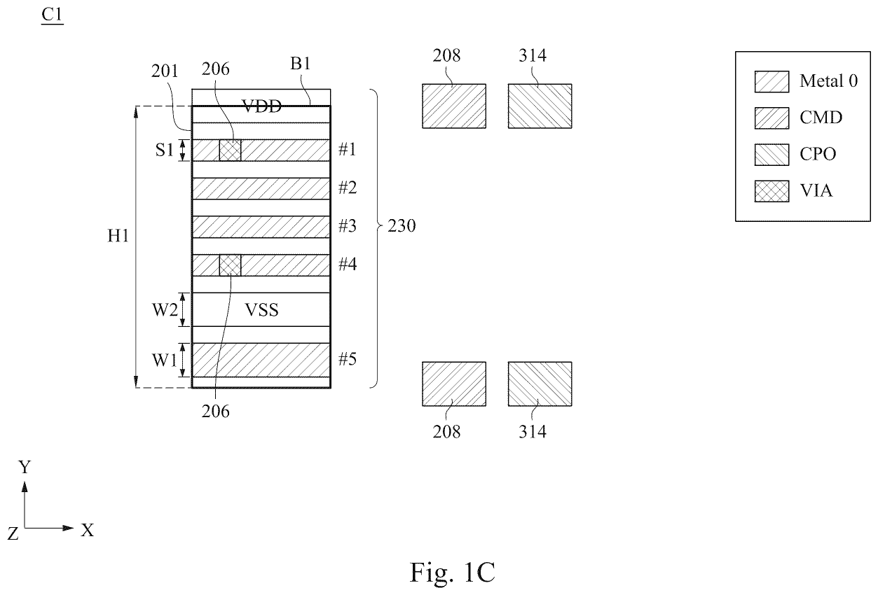

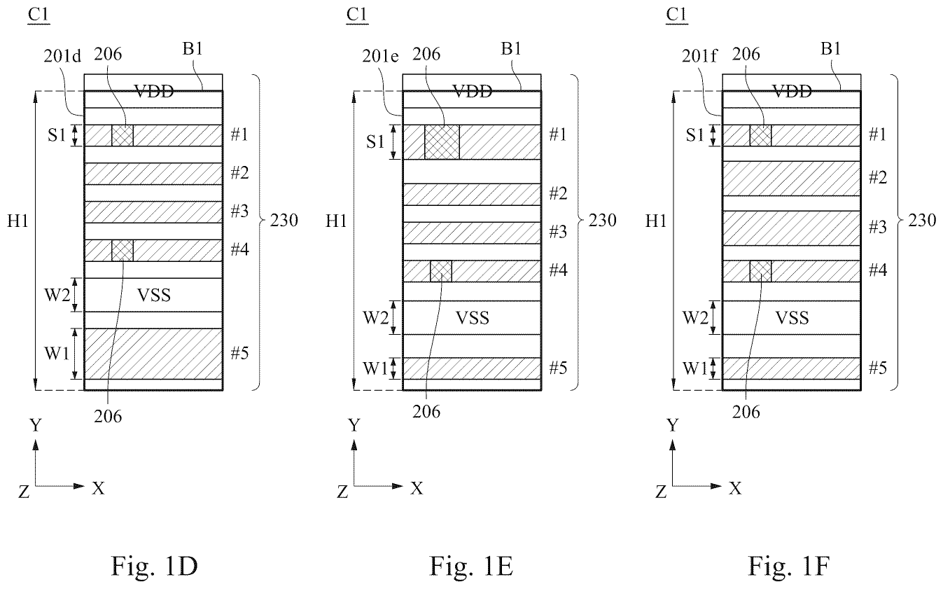

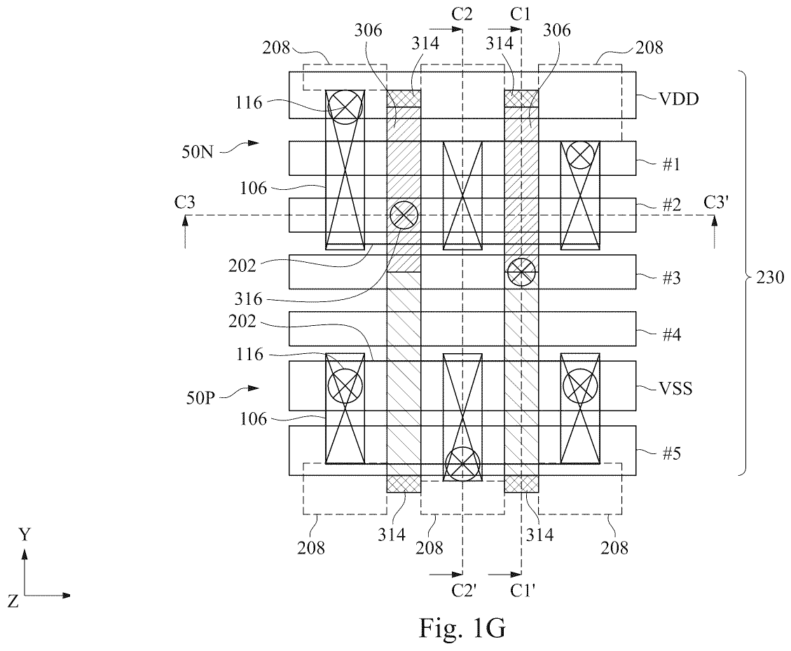

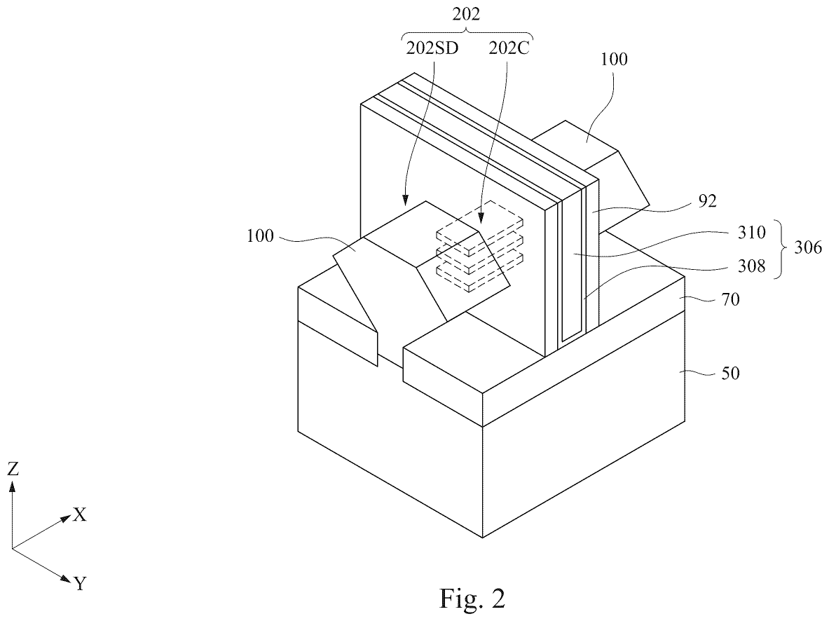

In some embodiments, one-half-height (OHH) cells can adopt an Metal-0 (M0) layout style similar to single-height (SH) cells, resulting in the loss of an M0 track. This inefficiency may leads to suboptimal electrical resistance-capacitance (Rc) values, limiting the performance and speed of OHH cells. Therefore, the present disclosure in various embodiments provides a method to address the inefficiency in Metal-0 (M0) layout design for one-half-height (OHH) cells. Specifically, the width of M0 tracks from #1 to #5 (see FIG. 1C) can be increased, and thus the size of the via associated with the M0 layer can be expanded to reduce resistance (Rc). Additionally, a functionless (or redundant) M0 track (i.e., M0 track #6 track, not shown) can be removed. Furthermore, no additional mask is required for implementing this new layout. Therefore, these improvements can collectively enhance the electrical performance of the OHH cells by reducing Rc and enabling faster operational speeds.

Reference is made to FIGS. 1A-1F. FIG. 1A is a fragmentary diagrammatic top view of an integrated circuit (IC) chip, in portion or entirety, in accordance with some embodiments of the present disclosure. FIG. 1B illustrates a layout diagram in accordance with some embodiments of the present disclosure, wherein the structural components located at different height levels within a semiconductor device are represented in a disassembled manner, allowing for a clearer visualization of the spatial relationships and alignment between the various functional layers. For example, the power rails VDD and VSS and the Metal-0 (M0) tracks #1 to #5 (see FIG. 1C), which are responsible for signal routing distinctly separated from the active regions 202, 204, 222, and 224 (or p-type and n-type transistors). By disassembling the layout, it can illustrate how these tracks align with the active regions 202, 204, 222, and 224 and power rails VDD and VSS to enable electrical interconnections. This separation also can illustrate how the M0 tracks can overlap specific layers, such as CMD or CPO (see FIG. 1C), while maintaining alignment with the gate structures 306 and 326 and the active regions 202, 204, 222, and 224. FIG. 1C is a local enlarged view of the semiconductor structure according to a region C1 in FIG. 1B, focusing on the M0 tracks, vias, and other layers. FIGS. 1D-1F illustrate semiconductor structures corresponding to FIG. 1C in accordance with some embodiments of the present disclosure.

FIG. 1A is a fragmentary diagrammatic top view of an integrated circuit (IC) chip 10, in portion or entirety, in accordance with some embodiments. The IC chip 10 may include various passive microelectronic devices and active microelectronic devices, such as resistors, capacitors, inductors, diodes, p-type field effect transistors (PFETs), n-type field effect transistors (NFETs), metal-oxide semiconductor FETs (MOSFETs), complementary metal-oxide-semiconductor (CMOS) transistors, bipolar junction transistors (BJTs), laterally diffused MOS (LDMOS) transistors, high voltage transistors, high frequency transistors, other suitable components, or combinations thereof. The various microelectronic devices can be configured to provide the IC chip 10 with functionally distinct regions, such as a core region (also referred to as a logic region), a memory region (e.g., a static random access memory (SRAM) region), an analog region, a peripheral region (also referred to as an input/output (I/O) region), a dummy region, and/or other suitable regions.

As shown in FIG. 1A, the IC chip 10 includes a logic region 20. The logic region 20 may include arrays 200 and 220 (see FIG. 1B) of circuit cells having various logic cells or standard (STD) cells. In some embodiments, devices in the array 200 can be a different device type than those in the array 220. In some embodiments, devices in the array 200 can be the same device type as those in the array 220. For example, the logic cells or STD cells may include transistors and interconnect structures that combine to provide a logic device and/or a logic function, such as an inverter, an AND, a NAND, an OR, an NOR, a NOT, an XOR, an XNOR, other suitable logic devices, or a combination thereof. FIG. 1A has been simplified for the sake of clarity to better understand the inventive concepts of the present disclosure. Additional features can be added in the IC chip 10, and some of the features described herein can be replaced, modified, or eliminated in other embodiments of the IC chip 10.

Specifically, FIGS. 1B and 1C how cell units 201 in the array 200 are arranged and compare them to the cell units 221 in the array 220. The cell units 201 in the array 200 can have a cell height H1 greater than a cell height H2 of the cell units 221 in the array 220. By way of example but not limiting the present disclosure, the cell height H1 can be more than 1.2 times of cell height H2, such as about 1.2, 1.3, 1.4, 1.5, 1.6, 1.7, 1.8, 1.9, or 2.0. For example, the cell unit 201 can be a one-half-height (OHH) standard cell, and the cell unit 221 can be a single-height (SH) cell. Additionally, FIGS. 1A and 1B show how the meal layer 230 (e.g., Metal-0 (M0) layer) is used in the cells 201, focusing on making the design more efficient and effective. The layout has been redesigned to enhance performance while keeping the manufacturing process simple.

In FIG. 1B, the cell unit 220 on the left side can include several M0 tracks in the metal layer 230 for power (e.g., power rails denoted as VDD and VSS) and signal routing. The M0 tracks in cell units 221 are narrower compared to the cell units 201. Shown in the right portions of FIG. 1B, these cell units 201 can be taller (e.g., are 1.5 times) than cell units 221, which in turn allows the design to improve the M0 tracks by widening tracks and removing unnecessary ones, which results in better power delivery and signal clarity.

In some embodiments, the term “M0 track” can be derived from its role in the M0 layer of a semiconductor chip. For example, the M0 layer can be the first metal interconnect layer that is deposited and patterned during the fabrication of integrated circuits (ICs). In some embodiments, the M0 layer can lay closest to the semiconductive substrate, which contains the transistors and other active components. The term “M0” may indicate that its position as the base metal layer in the hierarchy of interconnects, with subsequent layers named M1, M2, etc., as they are added on top of the M0 layer. The M0 tracks can include power rails (e.g., power rails VDD and VSS) for delivering power to the circuit, and signal transmission line for carrying signals between transistors and other elements. In some embodiments, the word “track” can refer to the individual conductive lines or paths within the M0 layer. These paths can carry electrical currents efficiently. In some embodiments, the tracks can be organized in a grid-like pattern to maximize space utilization and ensure connectivity. The M0 tracks can connect the power rails VDD and VSS to the source/drain regions of the transistors and other internal parts, ensuring reliable electrical performance. In some embodiments, the track and/or the power rail VDD/VSS can be interchangeable referred to as a metal track, metal line, metal pattern, or conductive line.

As shown in FIGS. 1B and 1C, the cell unit 201 (e.g., OHH layout) can include five tracks (e.g., M0 tracks #1 to #5) in metal layer 230 (e.g., M0 tracks), which in turn allows for delivering better electrical performance. In some embodiments, the tracks in the cell unit 201 can be evenly spaced across the cell height H1. In some embodiments, a redundant track (e.g., M0 track #6 not shown) has been removed to simplify the layout and improve efficiency. By removing unnecessary tracks and optimizing the remaining ones, the layout can achieve better functionality while keeping costs low. For example, wider tracks in the cell unit 201 can help lower electrical resistance and capacitance (Rc), enabling faster signals and better power efficiency compared to SH units. The power rail VDD located in the cell unit can provide power (e.g., positive voltage), while the power rail VSS located in the cell unit can act as the ground. The power rails VDD and VSS can directly connected to the internal components using the M0 tracks and vias, ensuring smooth and consistent power flow throughout the cell unit.

The array 200 can include active regions 202 and 204. In some embodiments, the active region 202 forms a first conductivity type transistor, while the active region 204 forms a second conductivity type transistor, which is of opposite conductivity to the first. For example, the first conductivity type transistor can be a p-type transistor, and the second conductivity type transistor can be an n-type transistor. Similarly, the array 220 can include active regions 222 and 224. In some embodiments, the active region 222 forms a first conductivity type transistor, while the active region 224 forms a second conductivity type transistor with opposite conductivity. For instance, the first conductivity type transistor can be a p-type transistor, and the second conductivity type transistor can be an n-type transistor.

As shown in FIG. 1B, the active region 202 can include a channel region 202C and source/drain regions 202SD located on opposite sides of the channel region 202C. Similarly, the active region 204 can include a channel region 204C and source/drain regions 204SD located on opposite sides of the channel region 204C. Transistors in the cell unit 201 can have gate structures 306 extending across the channel regions 202C and 204C of the active regions 202 and 204, facilitating control of the channel regions 202C and 204C, enabling efficient transistor operation and signal modulation within the array 200. In some embodiments, the channel region 202C can be interchangeable referred to as a channel feature, a channel layer, a channel pattern, or a semiconductive nanostructure. Likewise, the active region 222 can include a channel region 222C and source/drain regions 222SD located on opposite sides of the channel region 222C. Similarly, the active region 224 can include a channel region 224C and source/drain regions 224SD located on opposite sides of the channel region 224C. Transistors in the cell unit 221 can have gate structures 326 extending across the channel regions 222C and 224C of the active regions 222 and 224, facilitating control of the channel regions 222C and 224C, enabling efficient transistor operation and signal modulation within the array 220.

As shown in FIG. 1C, vias 206 can be vertical connectors that link the M0 tracks to the subsequent overlying layer (e.g. M1 layer). The larger size of the vias 206 can reduce electrical resistance, improving performance and ensuring stability, even at high speeds. The cut metal-to-diffusion (CMD) region 208 and cut poly (CPO) region (e.g., dielectric regions 314) can be placed near the M0 tracks to assist with signal routing and ensure the design remains compact and functional. The CMD process can be performed to form CMD region 208 used in semiconductor design and manufacturing to manage and optimize the layout of metal interconnects, such as adjacent source/drain (S/D) contacts, ensuring proper electrical isolation and efficient routing within integrated circuits (ICs). For example, the CMD process may include etching the source/drain contacts to create openings at predefined locations, followed by the deposition of dielectric materials into these openings to form the CMD region 208. This dielectric material can serve to electrically isolate the source/drain contacts from adjacent structures, reducing crosstalk and enhancing the integrity of the circuit layout. After the dielectric material is deposited, a planarization step, such as chemical mechanical polishing (CMP), may be performed to ensure the surface is leveled. In some embodiments, a CPO process can be performed applied to the gate strip (or polysilicon layer) in semiconductor devices to form the CPO region. For example, a photoresist layer can be applied over the gate strip and using photolithography to pattern the desired regions for the CPO region (or CPO structure). Subsequently, an anisotropic etching can be performed to remove the unprotected regions of the gate strip to define the gate structures (e.g., gate structures 306). Subsequently, a dielectric material, such as silicon oxide or silicon nitride, can be deposited into the openings created during the etching process to electrically isolate the gate structures from adjacent components. Subsequently, a planarization step, such as CMP, can be conducted to ensure a flat and uniform surface for subsequent process layers. The CPO region can be used to form the gate structures of transistors, ensuring that polysilicon regions can be defined and isolated, contributing to the functionality and alignment of the overall circuit. The CPO process can remove some polysilicon features, simplifying the layout and making the design more robust and manufacturable. In CMOS designs, the CPO regions can ensure that the gates are aligned and isolated from each other, enhancing the electrical performance of the transistor.

In some embodiments, the number of M0 tracks for signal transmission in the M0 layer within the cell unit 201 is greater than the number of M0 tracks for signal transmission in the M0 layer within the cell unit 221. For example, the number of M0 tracks in the M0 layer within the cell unit 201 is five, while the number of M0 tracks in the M0 layer within the cell unit 221 is four. The additional M0 track in the cell unit 201 can provide greater flexibility for routing and signal integrity. In some embodiments, the M0 tracks for signal transmission in the M0 layer within the cell unit 201 can be electrically connected to the M0 tracks for signal transmission in the M0 layer within the cell unit 221. Such connections can enable seamless data and power transfer between different cells. In some embodiments, the M0 tracks for signal transmission in the M0 layer within the cell unit 201 can be electrically isolated from the M0 tracks for signal transmission in the M0 layer within the cell unit 221. This isolation can enhance design modularity and reduce interference between adjacent cell units.

As shown in FIGS. 1B and 1C, the M0 tracks and the power rails VSS/VDD within the array 200 can have dimensions (e.g., width) W1 and W2 in the Y-direction, while the M0 tracks and the power rails VSS/VDD within the array 220 can have dimensions (e.g., width) W3 and W4 in the Y-direction. In some embodiments, the dimension W1 of the M0 tracks within the array 200 can be greater than the dimension W2, W3, and/or W4 of the M0 tracks within the arrays 200 and 220. By way of example but not limiting the present disclosure, the dimension W1 can be more than 1.2 times the dimension W2, W3, and/or W4, such as about 1.2, 1.3, 1.4, 1.5, 1.6, 1.7, 1.8, 1.9, 2.0, 2.5, 3, 3.5, 4, 4.5, or 5 times. In some embodiments, the dimension W1 of the M0 tracks within the array 200 can be substantially equal to or less than the dimension D1 of the power rails VSS/VDD within the array 200. In some embodiments, the dimension W2 of the power rails VSS/VDD within the array 200 can be substantially equal to or different from the dimension W1 of the power rails VSS/VDD within the array 220.

As shown in FIGS. 1B and 1C, the active regions 202 and 204 within the array 200 can have a dimension D1 (e.g., width) in the Y-direction, while the active regions 222 and 224 within the array 220 can have a dimension D2 (e.g., width) different from the dimension D1 in the Y-direction. In some embodiments, the dimension D1 of the active regions 202 and 204 within the array 200 can be greater than the dimension D2 of the active regions 222 and 224 within the array 220. By way of example but not limiting the present disclosure, the dimension D1 can be more than 1.2 times the dimension D2, such as about 1.2, 3, 4, 5, 6, 7, 8, 9, or 10 times. These variations in dimensions allow for improved electrical performance and better utilization of space within the array. In some embodiments, the dimension D1 of the active regions 202 and 204 within the array 200 can be greater than the dimensions (e.g., width) W1 and W2 of the M0 tracks and the power rails VSS/VDD.

As shown in FIGS. 1B and 1C, the via 206 within the array 200 can have a dimension S1 (e.g., width) in the Y-direction. In some embodiments, the dimension S1 can be greater than the dimension W3 and/or W4 of the M0 tracks and the dimension D2 of the active regions 222 and 224 within the array 220. By way of example but not limiting the present disclosure, the dimension S1 can be more than 1.2 times the dimension W3, W4, and/or D2, such as about 1.2, 1.3, 1.4, 1.5, 1.6, 1.7, 1.8, 1.9, 2.0, 2.5, 3, 3.5, 4, 4.5, or 5 times. These larger via dimensions help to improve electrical connectivity and reduce resistance, thereby enhancing overall circuit performance.

As shown in FIG. 1B, the M0 tracks and power rails VSS/VDD within the array 200 can be misaligned with the M0 tracks and power rails VSS/VDD within the array 220 in the X-direction. This misalignment can occur due to differences in the design requirements of the respective arrays, allowing for more efficient routing and optimization of power delivery and signal integrity between the arrays 200 and 220. By adjusting the relative positions of the tracks and power rails in the X-direction, the region 20 can accommodate varying cell heights, track widths, and routing densities. In some embodiments, the footprints of the power rails VDD and VSS within the array 200 may not be confined to the boundary B1 of the cell unit 201. For example, the footprints of the power rails VDD and VSS may overlap with the active regions 202 and 204. In some embodiments, the footprints of the power rails VDD and VSS can be positioned entirely within the active regions 202 and 204, without extending to edges 202s and 204s of the active regions 202 and 204. In some embodiments, the footprints of the power rails VDD and VSS can be positioned between active regions 202 and 204, which belong to different conductivity types. For example, the active region 202 may be associated with a p-type transistor, while active region 204 may correspond to an n-type transistor. By situating the power rails VDD and VSS between the active regions 202 and 204, the region 20 can achieve effective segregation of power delivery pathways and signal routing areas.

As shown in FIG. 1C, the footprints of the M0 tracks (e.g., M0 tracks #1 to #5) can overlap with the CMD region 208 and/or the CPO region (e.g., dielectric regions 314), enabling streamlined signal routing and efficient utilization of the layout space by integrating the metal tracks with the structural layers responsible for isolation and gate definition. In some embodiments, the M0 tracks (e.g., M0 tracks #1 to #5) can be positioned closer to the boundary B1 of the cell unit 200 compared to the power rails VDD and VSS, allowing for better spatial separation between power delivery paths and signal routing paths, reducing the likelihood of interference or crosstalk. Additionally, overlapping the M0 tracks with CMD region 208 and/or CPO region can enhance layout compactness and manufacturability. The CMD region 208 isolates adjacent source/drain contacts, while the CPO region can define and isolates gate structure. The co-location of M0 tracks with these layers can allow for tighter integration of metal and structural layers, reducing the overall footprint of the cell unit 200.

Reference is made to FIGS. 1D to 1F. FIGS. 1D to 1F illustrate cell units 201d, 201e, and 201f in accordance with some embodiments of the present disclosure. While FIGS. 1D to 1F illustrate embodiments of cell units 201d, 201e, and 201f with different structural configurations than the cell unit 201 in FIGS. 1A-1C, the present disclosure may repeat reference numerals and/or letters in the various examples. This repetition is for simplicity and clarity and does not dictate a relationship between the various embodiments and/or configurations discussed.

As shown in FIG. 1D, a difference between the embodiment in FIGS. 1A-1C and the embodiment in FIG. 1D is that the M0 track closest to the boundary B1 of the cell unit 201c (e.g., M0 track #5) has a dimension W1 that is greater than the dimension W2 of the power rail VSS/VDD. This configuration can provide enhanced signal routing capabilities for the track M0 closest to the cell boundary B1 for inter-cell communication in dense layouts. The increased dimension W1 can allow for lower resistance and improved electrical performance.

As shown in FIG. 1E, a difference between the embodiment in FIGS. 1A-1C and the embodiment in FIG. 1E is that the M0 tracks located between the power rails VSS and VDD (e.g., M0 tracks #1 to #4) can have different dimensions W1. For example, the width of M0 track #1 can be greater than the widths of M0 tracks #2 to #4. In some embodiments, the width of M0 track #1 can also be greater than the width of M0 track #5. This configuration optimizes the layout for signal integrity and routing priority, as wider tracks can support higher current densities and faster signal propagation. Moreover, in some embodiments, the via 206 located on M0 track #1 can have a dimension S1 that is greater than the dimension W3 and/or W4 of the M0 tracks and the dimension D2 of the active regions 222 and 224 within the array 220. This larger via dimension improves vertical connectivity and reduces electrical resistance, ensuring stable performance under high-speed operations.

As shown in FIG. 1F, a difference between the embodiment in FIGS. 1A-1C and the embodiment in FIG. 1F is that the M0 tracks located between the power rails VSS and VDD (e.g., M0 tracks #1 to #4) can have different dimensions W1. For example, the widths of M0 tracks #2 and #3 can be greater than the widths of M0 tracks #1 and #4. In some embodiments, the widths of M0 tracks #2 and #3 can also be greater than the width of M0 track #5. This configuration can enhance the central signal routing capacity of the cell, allowing for more efficient signal distribution and reducing congestion in high-density layouts. The wider central tracks (e.g., Mo tracks #2 and #3) can also accommodate higher current loads and provide improved signal reliability.

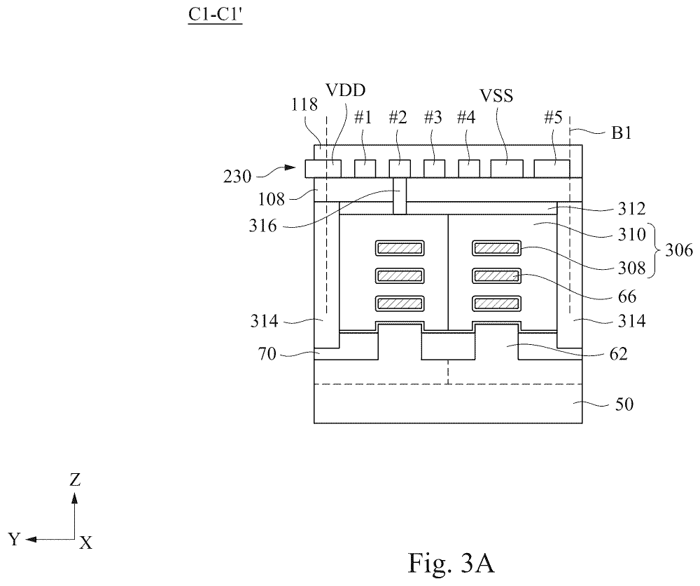

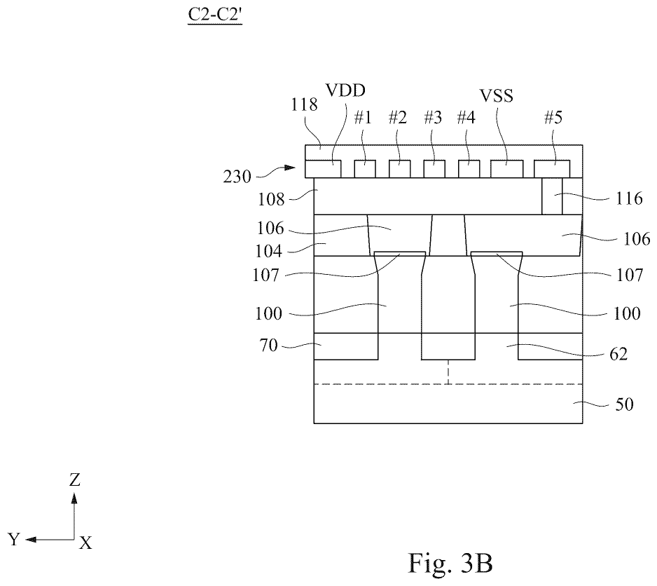

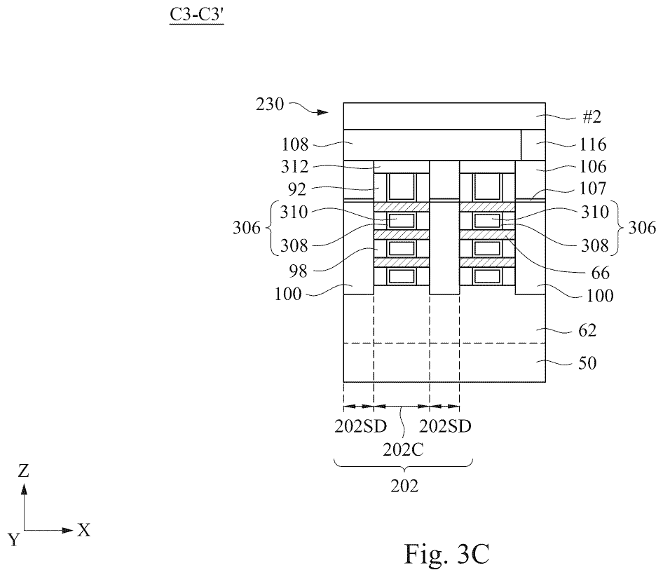

Reference is made to FIGS. 1G and 2-3C. FIG. 1G illustrates a fragmentary diagrammatic top view (or layout) of a semiconductor structure in a region (e.g., logic region) of an IC chip, in accordance with some embodiments of the present disclosure. Specifically, FIG. 1F illustrates the structural components of a semiconductor layout presented in a stacked manner, where elements at different height levels are superimposed to demonstrate their spatial relationships and functional integration. For instance, the layout highlights the placement of power rails VDD and VSS, overlaid with the M0 tracks, active regions, and vias. This representation underscores the alignment and connectivity of these elements, facilitating an understanding of the vertical interactions within the semiconductor design. FIG. 2 is a perspective view of a GAA transistor in the array of circuit cells, that can be used to implement the layout shown in FIG. 1G, in accordance with some embodiments of the present disclosure. FIGS. 3A-3C illustrates cross-sectional views of the semiconductor structure along lines C1-C1′, C2-C2′, and C3-C3′, respectively, in FIG. 1G, in accordance with some embodiments of the present disclosure.

Referring to FIG. 2, a perspective view of an exemplary GAA transistor is illustrated. The GAA transistor can be formed over a substrate 50. The substrate 50 may contains a semiconductor material, such as bulk silicon (Si). The GAA transistor also includes one or more channel regions 202C (dash lines) extending in the X-direction and vertically stacked (or arranged) in the Z-direction. More specifically, the channel regions 202C are spaced apart from each other in the Z-direction. In some embodiments, the channel regions 202C may also be referred to as nanostructures, channels, channel layers, channel patterns, nanosheets, or nanowires.

The GAA transistor 200 further includes a gate structure 306 including a gate dielectric layer 308 and a gate electrode layer 310. The gate dielectric layer 308 wraps around the channel regions 202C and the gate electrode layer 310 wraps around the gate dielectric layer 308 (not shown in FIG. 2, may refer to FIGS. 3A to 3C). In other words, the gate structure 306 can interface at least three surfaces of the channel region 202C of the active region AC. As shown in FIG. 2, gate spacers 92 are formed on sidewalls of the gate structure 306 and over the channel regions 202C.

The GAA transistor further includes source/drain structures 100. As shown in FIG. 2, two source/drain structures 100 are on opposite sides of the gate structure 306. The channel regions 202C extend in the X-direction to connect one source/drain structure 100 to the other source/drain structure 100. The source/drain structures 100 may also be referred to as source/drains, source/drain patterns, source/drain features, source/drain structures, source/drain regions, epitaxial structures. In some embodiments, source/drain feature(s) may refer to a source or a drain, individually or collectively dependent upon the context.

The isolation structures 70 are formed over the substrate 50 and under the gate dielectric layer 308, the gate electrode layer 310, and the gate spacers 92. The isolation structures 70 are used for isolating the GAA transistor from other devices. In some embodiments, the isolation structures 70 may include different structures, such as a shallow trench isolation (STI) structure or a deep trench isolation (DTI) structure. Therefore, the isolation structures 70 are also referred to as STI features or DTI features.

Referring to FIGS. 1G and 3A-3C, A substrate 50 may be a semiconductor substrate, such as a bulk semiconductor, a semiconductor-on-insulator (SOI) substrate, or the like, which may be doped (e.g., with a p-type or an n-type dopant) or un-doped. The substrate 50 may be a wafer, such as a silicon wafer. The substrate 50 can have a first conductivity type device region 50N (see FIG. 1G) and a second conductivity type device region 50P (see FIG. 1G). The first conductivity type device region 50N can be for forming n-type devices, such as NMOS transistors, e.g., n-type nanostructure-FETs, and the second conductivity type device region 50P can be for forming p-type devices, such as PMOS transistors, e.g., p-type nanostructure-FETs. The first conductivity type device region 50N may (or may not) be physically separated (not separately illustrated) from the second conductivity type device region 50P, and any number of device features (e.g., other active devices, doped regions, isolation structures, etc.) may be disposed between the first conductivity type device region 50N and the second conductivity type device region 50P.

A fin structure 62 can be formed in the substrate 50. The nanostructures 66 (see FIGS. 3A and 3C) over the fin structure 62 may be act as a channel region 202C (see FIG. 3C) of the active region 202 in the semiconductor device. An isolation structures 70 (see FIGS. 3A and 3B) can be formed over the substrate 50 and laterally surrounding the fin structure 62. A gate structure 306 can be formed to wrap around the respective nanostructure 66. In some embodiments, the gate structure 306 may include the gate dielectric layer 308 and the gate electrode layer 310 over the gate dielectric layer 308. A hard mask layer 312 (see FIGS. 3A and 3C) can be formed over the gate structure 306. Gate spacers 92 (see FIG. 3C) can be formed on opposite sidewalls of the gate structure 306. In some embodiments, the gate spacers 92 may be formed of silicon oxide, silicon nitride, silicon oxynitride, combinations thereof. Inner spacers 98 (see FIG. 3C) are formed on opposite ends of each of the nanostructures 64.

Source/drain structures 100 (see FIGS. 3B and 3C) formed in the first conductivity type device region 50N may be referred to as n-type source/drain structures 100, and the source/drain structures 100 formed in the second conductivity type device region 50P may be referred to as p-type source/drain structures 100. In some embodiments, the source/drain structures 100 exert stress on channel regions of the nanostructures 66 within the first conductivity type device region 50N and/or within the second conductivity type device region 50P, thereby improving performance. In some embodiments, the gate spacers 92 can be used to separate the source/drain structures 100 from the gate structure 306, and the inner spacers 98 can be used to separate the source/drain structures 100 from the nanostructures 66 by an appropriate lateral distance such that the source/drain structures 100 do not short out with subsequently formed gates of the resulting nanostructure-FETs. In some embodiments, silicide layers 107 (see FIGS. 3B and 3C) can be formed over the source/drain structures 100. In some embodiments, the silicide layer 107 may include titanium silicide (TiSi), nickel silicide (NiSi), cobalt silicide (CoSi), Ni-Pt, or combinations thereof.

An interlayer dielectric (ILD) layer 104 (see FIG. 3B) can be formed over the source/drain structures 100. In some embodiments, source/drain contacts 106 (see FIGS. 1G, 3B, and 3C) are formed in the ILD layer 104 and over the source/drain structures 100. In some embodiments, the source/drain contacts 106 can be formed by a self-aligned contact process using the hard mask layer 312 as a contact etch protection layer. Therefore, the hard mask layer 312 can be used to define self-aligned gate contact region and thus referred to as a self-aligned contact (SAC) structure or a SAC layer. In some embodiments, the dielectric regions 314 (see FIGS. 1G and 3A) can be formed on opposite ends of the gate electrode layer 310 after the forming of the hard mask layer 312. In some embodiments, each dielectric region 314 is a gate-cut structure for the gate structure.

An ILD layer 108 is deposited over the ILD layer 104. Subsequently, source/drain vias 116 (see FIGS. 1G, 3B, and 3C) are formed in the ILD layer 108 and land on the source/drain contacts 106. Gate vias 316 (see FIGS. 1G and 3A) are formed to pass through the ILD layer 108 and the hard mask layer 312 and land on the gate electrode layer 310. The source/drain vias 116 and/or the gate vias 316 may include a metal-containing material such as titanium nitride, titanium oxide, tungsten, cobalt, ruthenium, aluminum, copper, combinations thereof, multi-layers thereof, or the like. The ILD layer 108 may be made of an oxide, such as silicon oxide, a nitride, such as silicon nitride, the like, or a combination thereof.

A front-side interconnect structure can be formed over the front-side gate vias 316 and the front-side source/drain vias 116. The interconnect structure includes a plurality of metallization layers with a plurality of metallization vias or interconnects. Other embodiments may contain more or fewer metallization layers and corresponding more or fewer number of vias. The metal line illustrated here just for an example, and the metal line may be otherwise oriented (rotated 90 degrees or at other orientations). The front-side interconnect structure may include metal layer 230 (e.g., Metal-0 (M0) layer) include several M0 tracks for power (e.g., power rails VDD and VSS) and signal routing (e.g., M0 tracks #1 to #5). The tracks can be formed in an IMD (inter-metal dielectric) layer 118 (see FIGS. 3A and 3B). The tracks can be electrically connected to the gate electrode layers 310 through the gate vias 316 and electrically connected to the source/drain structures 100 through the source/drain vias 116 and the source/drain contacts 106.

The multiple components within array 220 and their positional relationships are similar to those within array 200 in terms of formation methods and general configuration. However, at least differences may exist: the circuit type, the cell height, and the M0 track configuration. Due to these similarities, this disclosure can focus on describing the relevant structures and manufacturing processes of array 200 using FIGS. 1G, 2-3C, and 4-10C while omitting a detailed description of array 220. For details regarding the multiple components within array 220, their positional relationships, and their formation methods, the descriptions provided in FIGS. 1G, 2-3C, and 4-10C for array 200 may be referenced. These figures outline the arrangement and alignment of various elements such as M0 tracks, active regions, power rails, and interconnect structures. The description may also cover the manufacturing process used to form these elements, including deposition, etching, and planarization steps, which are equally applicable to array 220 despite the noted differences.

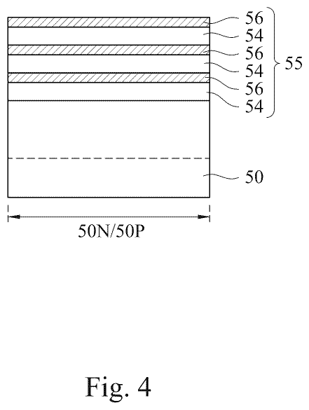

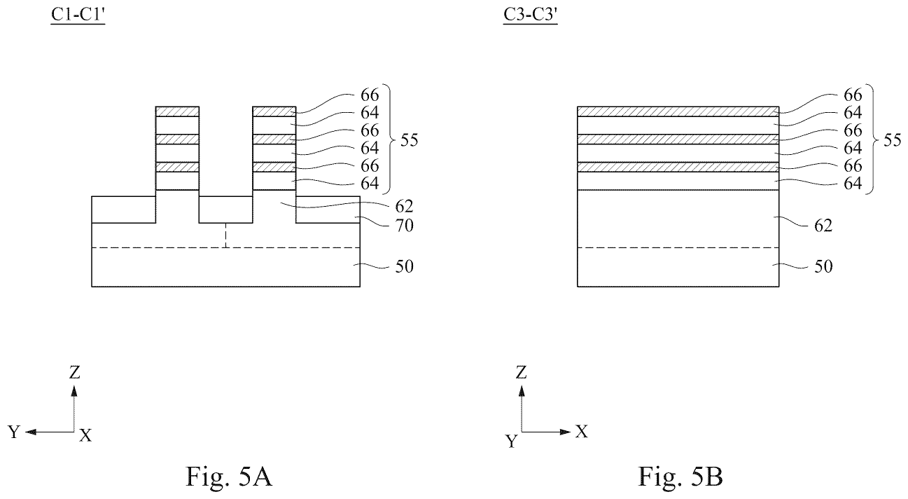

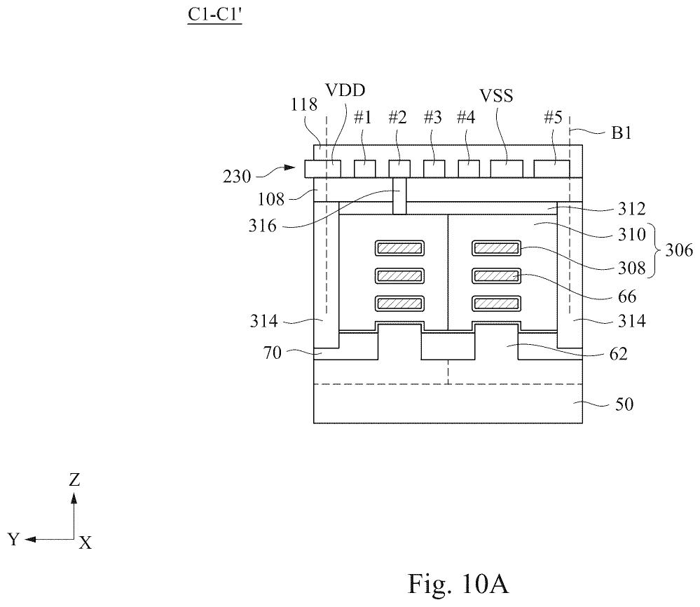

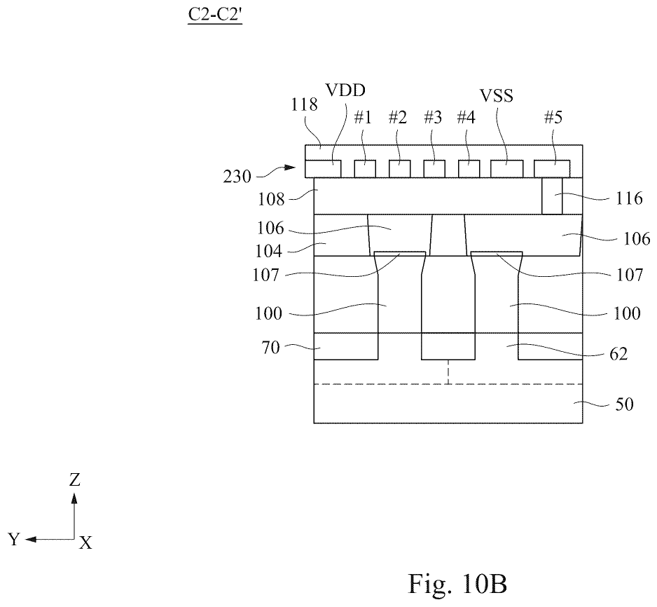

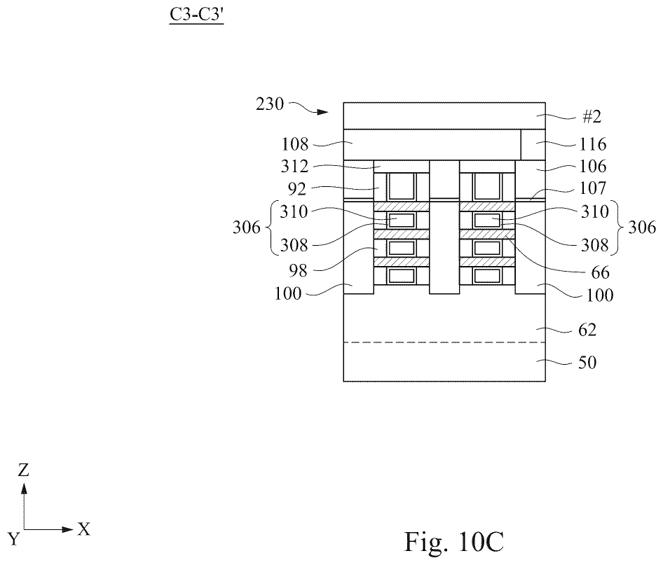

Reference is made to FIG. 4-10C. FIGS. 4, 5A, 6A, 7A, 8A, 9A, and 10A illustrate cross-sectional views obtained from reference cross-section C1-C1′ in FIG. 1G, in accordance with some embodiments of the present disclosure. FIGS. 5B, 6B, 7B, 8B, 9B, and 10B illustrate cross-sectional views obtained from reference cross-section C3-C3′ in FIG. 1G, in accordance with some embodiments of the present disclosure. FIG. 10C illustrates a cross-sectional view obtained from reference cross-section C2-C2′ in FIG. 1G, in accordance with some embodiments of the present disclosure. It is understood that additional operations can be provided before, during, and after the processes shown by FIGS. 4-10C, and some of the operations described below can be replaced or eliminated, for additional embodiments of the method. The order of the operations/processes may be interchangeable.

Reference is made to FIG. 4. The substrate 50 may be a semiconductor substrate, such as a bulk semiconductor, a semiconductor-on-insulator (SOI) substrate, or the like, which may be doped (e.g., with a p-type or an n-type dopant) or un-doped. The substrate 50 may be a wafer, such as a silicon wafer. An SOI substrate is a layer of a semiconductor material formed on an insulator layer. The insulator layer may be, for example, a buried oxide (BOX) layer, a silicon oxide layer, or the like. The insulator layer is provided on a substrate, such as a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 50 can have a first conductivity type device region 50N and a second conductivity type device region 50P. The first conductivity type device region 50N can be for forming n-type devices, such as NMOS transistors, e.g., n-type nanostructure-FETs, and the second conductivity type device region 50P can be for forming p-type devices, such as PMOS transistors, e.g., p-type nanostructure-FETs. The first conductivity type device region 50N may (or may not) be physically separated (not separately illustrated) from the second conductivity type device region 50P, and any number of device features (e.g., other active devices, doped regions, isolation structures, etc.) may be disposed between the first conductivity type device region 50N and the second conductivity type device region 50P. Although one first conductivity type device region 50N and one second conductivity type device region 50P are illustrated, any number of n-type regions 50N and p-type regions 50P may be provided. Subsequent figures describe processing steps that may be performed in either the n-type regions 50N or the p-type regions 50P unless otherwise noted.

A multi-layer stack 55 can be formed over the substrate 50, in accordance with some embodiments. The multi-layer stack 55 includes alternating first semiconductor layers 54 and second semiconductor layers 56. The first semiconductor layers 54 are formed of a first semiconductor material, and the second semiconductor layers 56 are formed of a second semiconductor material. The semiconductor materials may each be selected from the candidate semiconductor materials of the substrate 50. In the illustrated embodiment, and as subsequently described in greater detail, the first semiconductor layers 54 will be removed and the second semiconductor layers 56 will patterned to form channel regions (e.g., channel regions 202C shown in FIG. 2) for the nanostructure-FETs in both the first conductivity type device region 50N and the second conductivity type device region 50P. In such embodiments, the channel regions in both the first conductivity type device region 50N and the second conductivity type device region 50P may have a same material composition (e.g., silicon or another semiconductor material) and be formed simultaneously. The first semiconductor layers 54 are dummy layers that will be removed in subsequent processing to expose top surfaces and bottom surfaces of the second semiconductor layers 56. The first semiconductor material of the first semiconductor layers 54 is a material that has a high etching selectivity from the etching of the second semiconductor layers 56, such as silicon germanium. The second semiconductor material of the second semiconductor layers 56 is a material suitable for both n-type and p-type devices, such as silicon. The first semiconductor material and the second semiconductor material may have a high etching selectivity from the etching of one another.

The multi-layer stack 55 can be illustrated as including three of the first semiconductor layers 54 and three of the second semiconductor layers 56. It should be appreciated that the multi-layer stack 55 may include any number of the first semiconductor layers 54 and the second semiconductor layers 56. Each of the layers of the multi-layer stack 55 may be grown by a process such as vapor phase epitaxy (VPE) or molecular beam epitaxy (MBE), deposited by a process such as chemical vapor deposition (CVD) or atomic layer deposition (ALD), or the like.

Reference is made to FIGS. 5A and 5B. Fin structures 62 can be formed in the substrate 50, and first nanostructures 64 and second nanostructures 66 can be formed in the multi-layer stack 55, by etching trenches in the multi-layer stack 55 and the substrate 50. Forming the nanostructures 64/66 by etching the multi-layer stack 55 may further define first nanostructures 64 from the first semiconductor layers 54 and define second nanostructures 66 from the second semiconductor layers 56. In some cases, the nanostructures 64/66 over the fin structure 62 may be considered a nanostructure stack or the like. The etching may be any acceptable etch process, such as a reactive ion etch (RIE), neutral beam etch (NBE), the like, or a combination thereof. The etching may be anisotropic.

After the nanostructure stack is formed, isolation structures 70 (see FIG. 5A) can be formed over the substrate 50 and laterally surrounding the fin structure 62. In some embodiments, the isolation structures 70 may be in contact with sidewalls of the fin structure 62 of the substrate 50. The isolation structures 70 may be shallow trench isolation (STI) structures, suitable isolation structures, combinations of the foregoing, or the like. In some embodiments, the isolation structures 70 may be made of oxide (e.g., silicon oxide), nitride (e.g., silicon nitride), or combinations thereof.

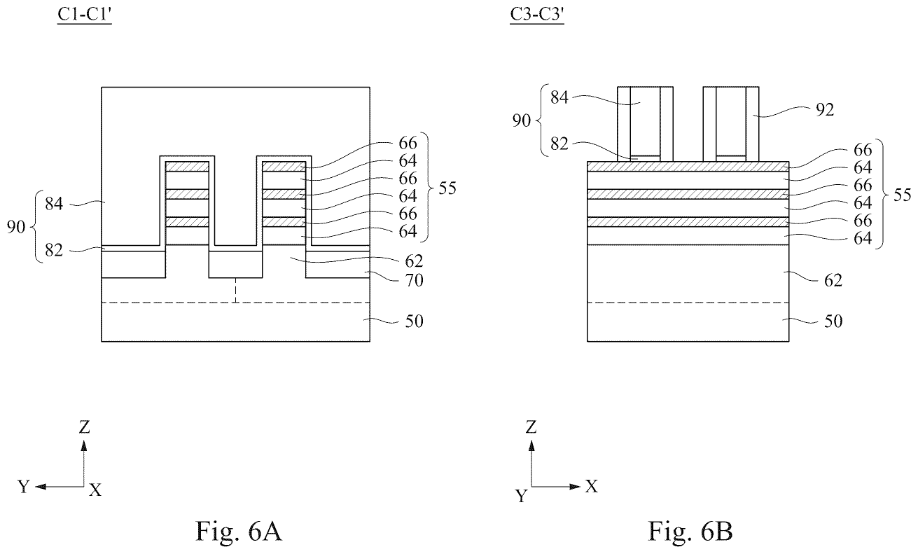

Reference is made to FIGS. 6A and 6B. A dummy gate structure 90 can be formed over the substrate 50 and crossing the nanostructure stack. In some embodiments, the dummy gate structure 90 can include a dummy gate dielectric 82 and a dummy gate electrode 84 over the dummy gate dielectric 82. The dummy gate dielectric 82 may be, for example, silicon oxide, silicon nitride, a combination thereof, or the like, and may be deposited or thermally grown according to acceptable techniques. The dummy gate electrode 84 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate electrode 82 and the dummy gate dielectric 84 may be formed by, for example, depositing a dummy dielectric layer and a dummy gate layer over the substrate 50, forming a patterned mask over the dummy gate layer, and then performing an etching process to the dummy dielectric layer and the dummy gate layer by using the patterned mask as etch mask. In some embodiments, the dummy gate electrode 84 may be deposited by physical vapor deposition (PVD), chemical vapor deposition (CVD), sputter deposition, or other techniques for depositing the selected material. In some embodiments, the dummy gate dielectric 82 may be formed by thermal oxidation.

Gate spacers 92 (see FIG. 6B) can be formed on opposite sidewalls of the dummy gate structure and on opposite sidewalls of the fin structure 62. In some embodiments, the gate spacers 92 may be formed of silicon oxide, silicon nitride, silicon oxynitride, combinations thereof. In some embodiments, the gate spacers 92 may be formed by, for example, depositing a spacer layer blanket over the substrate, and then performing an anisotropic etching process to remove horizontal portions of the spacer layer, such that vertical portions of the spacer layer remain on sidewalls of the dummy gate structure and on sidewalls of the fin structure 62. In some embodiments, the spacer layer may be deposited using techniques such CVD, ALD, or the like.

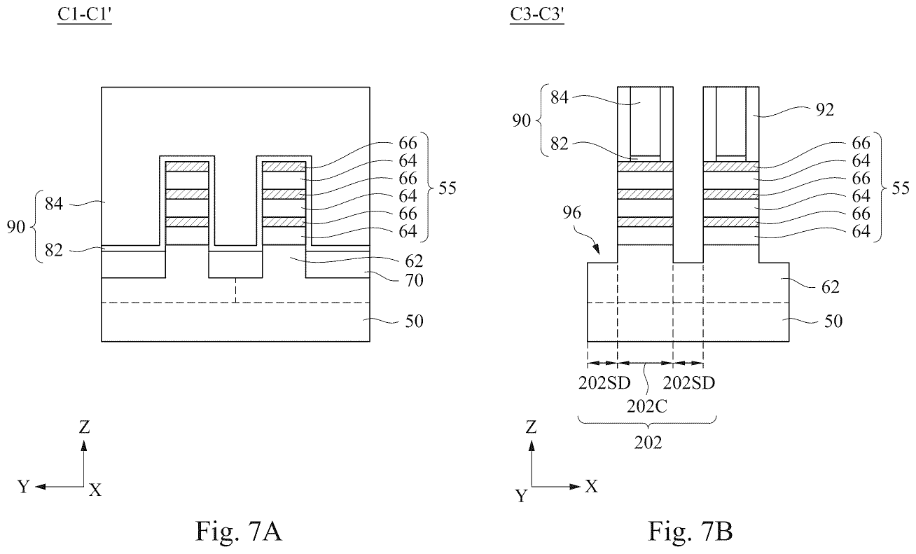

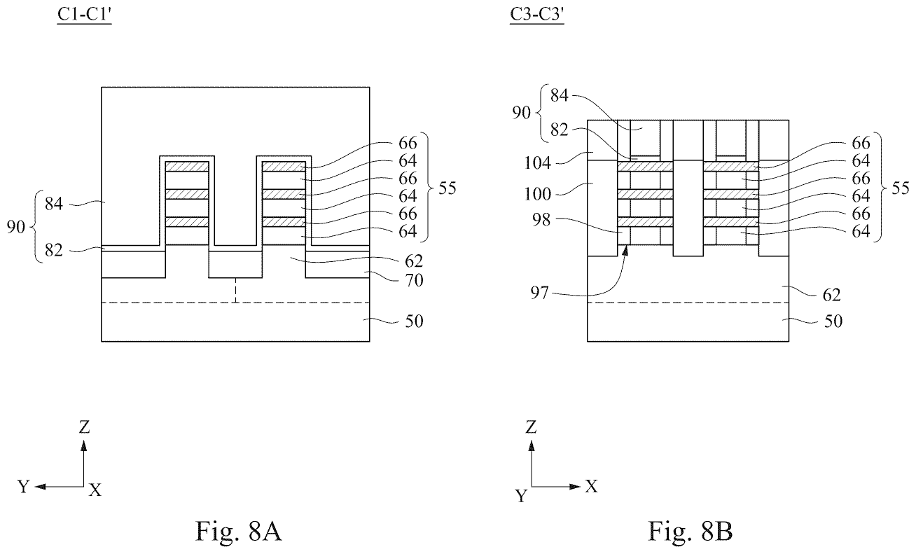

Reference is made to FIGS. 7A and 7B. Source/drain recesses 96 (e.g., within source/drain regions 202SD of the multi-layer stack 55) as shown in FIG. 7B can be patterned in the fin structures 62 and the nanostructures 64/66 using anisotropic etching processes, such as RIE, NBE, or the like, in accordance with some embodiments. Epitaxial source/drain structures 100 (see FIG. 8B) can be subsequently formed in the source/drain recesses 96. In some embodiments, the gate spacers 92 and the dummy gates 84 mask portions of the fin structures 62 and the nanostructures 64/66 during the etching processes used to form the source/drain recesses 96. A single etch process or multiple etch processes may be used to etch each layer of the nanostructures 64/66 and/or the fin structures 62. Timed etch processes may be used to stop the etching of the source/drain recesses 96 after the source/drain recesses 96 reach a desired depth. In some embodiments, the fin structures 62 may be etched such that the bottom surfaces of the source/drain recesses 96 are about level with or higher than top surfaces of the STI regions 70. In other embodiments, bottom surfaces of the source/drain recesses 96 are lower than the top surfaces of the STI regions 70.

Reference is made to FIGS. 8A and 8B. After the source/drain recesses 96 are formed, inner spacers 98 (see FIG. 8B) are formed on opposite ends of each of the nanostructures 64. The inner spacers 98 may be deposited by a conformal deposition process, such as CVD, ALD, or the like. The inner spacer 98 may include a material such as SiN, SiOCN, SiCN, SIOC, although any suitable material, such as low-dielectric constant (low-k) materials having a k-value less than about 3.5, may be utilized. The inner spacers 98 can be formed by, for example, performing an etching process to laterally etch the nanostructures 64 to form sidewall recesses 97. In some embodiments, the sidewalls of the nanostructures 64 may be etched using isotropic etching processes, such as wet etching or the like. In some embodiments where the nanostructures 64 include, e.g., SiGe, and the nanostructures 66 include, e.g., Si, an etch process with tetramethylammonium hydroxide (TMAH), ammonium hydroxide (NH₄OH), or the like may be used to etch sidewalls of the nanostructures 64. Then, inner spacers 98 are formed in the sidewall recesses 97 on opposite ends of each of the nanostructures 64. In some embodiments, the inner spacers 98 may be formed by, for example, depositing a dielectric material blanket over the substrate 50 and filling the sidewall recesses and the gap, and then performing an anisotropic etching to remove portions of the dielectric material outside the sidewall recesses and the gap, leaving the remaining portions of the dielectric material in the sidewall recesses 97 as the inner spacers 98.

Source/drain structures 100 can be formed in the source/drain recesses 96. The source/drain structures 100 in the first conductivity type device region 50N may be referred to as n-type source/drain structures 100, and the source/drain structures 100 in the second conductivity type device region 50P may be referred to as p-type source/drain structures 100. The n-type source/drain structures 100 may be formed before, after, or simultaneously with the formation of the p-type source/drain structures 100. The source/drain structures 100 may be formed by an epitaxy process, such as such as vapor phase epitaxy (VPE), molecular beam epitaxy (MBE), or the like. The source/drain structures 100 may be in-situ doped, and/or may be implanted, with an n-type or p-type dopant.

In some embodiments, the source/drain structures 100 exert stress on channel regions of the nanostructures 66 within the first conductivity type device region 50N and/or within the second conductivity type device region 50P, thereby improving performance. The source/drain structures 100 can be formed in the source/drain recesses 96 such that each dummy gate electrode 84 of the second conductivity type device region 50P is disposed between respective neighboring pairs of the source/drain structures 100. In some embodiments, the gate spacers 92 can be used to separate the source/drain structures 100 from the dummy gates 84, and the inner spacers 98 can be used to separate the source/drain structures 100 from the nanostructures 66 by an appropriate lateral distance such that the source/drain structures 100 do not short out with subsequently formed gates of the resulting nanostructure-FETs.

The source/drain structures 100 may be implanted with dopants to form source/drain regions, followed by an annealing process. The source/drain regions may have an impurity concentration of between about 1×10¹⁹ atoms/cm³ and about 1×10²² atoms/cm³. In some embodiments, the source/drain structures 100 may be in situ doped during growth. After the implants of the first conductivity type device region 50N and the second conductivity type device region 50P, an annealing process may be performed to repair implant damage and to activate the p-type and/or n-type impurities that were implanted.

For example, the source/drain structures 100 in the first conductivity type device region 50N may be formed by masking the second conductivity type device region 50P. Then, n-type source/drain structures 100 can be epitaxially grown in the source/drain recesses 96 in the first conductivity type device region 50N. The n-type source/drain structures 100 may include any acceptable material appropriate for n-type nanostructure-FETs. For example, if the nanostructures 66 are silicon, the n-type source/drain structures 100 may include materials exerting a tensile strain on the nanostructures 66, such as silicon, silicon carbide, phosphorous doped silicon carbide, silicon phosphide, or the like. An n-type impurity implant can be performed on the n-type source/drain structures 100 in the second conductivity type device region 50P. The n-type impurities may include phosphorus, arsenic, antimony, the like, or combinations thereof.

The source/drain structures 100 in the second conductivity type device region 50P may be formed by masking the first conductivity type device region 50N. Then, p-type source/drain structures 100 can be epitaxially grown in the source/drain recesses 96 in the second conductivity type device region 50P. The p-type source/drain structures 100 may include any acceptable material appropriate for p-type nanostructure-FETs. For example, if the nanostructures 66 are silicon, the p-type source/drain structures 100 may include materials exerting a compressive strain on the nanostructures 66, such as silicon germanium, boron doped silicon germanium, germanium, germanium tin, or the like. A p-type impurity implant may be performed on the p-type source/drain structures 100 in the second conductivity type device region 50P. The p-type impurities may include boron, boron fluoride, indium, the like, or combinations thereof.

Afterwards, an interlayer dielectric (ILD) layer 104 can be formed over the source/drain structures 100. Then, a planarization process, such as CMP, is performed to remove excess materials of the ILD layer 104 until the dummy gate structure 90 is exposed. In some embodiments, the ILD layer 104 may include silicon oxide, silicon nitride, silicon oxynitride, tetraethoxysilane (TEOS), phosphosilicate glass (PSG), borophosphosilicate glass (BPSG), low-k dielectric material, and/or other suitable dielectric materials. Examples of low-k dielectric materials include, but are not limited to, fluorinated silica glass (FSG), carbon doped silicon oxide, amorphous fluorinated carbon, parylene, bis-benzocyclobutenes (BCB), or polyimide. The ILD layer 104 can be formed using, for example, CVD, ALD or other suitable techniques.

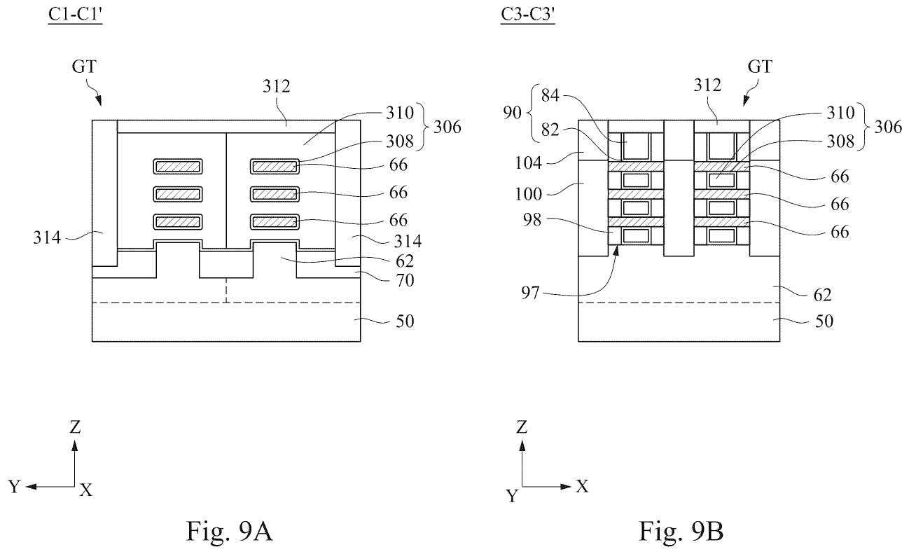

Reference is made to FIGS. 9A and 9B. The dummy gate structure 90 including the dummy gate dielectric 82 (see FIG. 8B) and the dummy gate electrode 84 (see FIG. 8B) can be removed to form gate trench GT between the gate spacers 92. Then, an etching process is performed to remove the nanostructures 64 (see FIG. 8B), such that the nanostructures 66 can be suspended over the substrate 50.

Subsequently, a gate dielectric layer 308 can be formed on exposed surfaces of the nanostructures 66. Then, a gate electrode layer 310 can be formed in the gate trench GT and over the gate dielectric layer 308. Accordingly, a gate structure 306 can be formed. The gate structure 306 may wrap around the respective nanostructure 66. In some embodiments, the gate structure 306 may include the gate dielectric layer 308 and the gate electrode layer 310 over the gate dielectric layer 308. In some embodiments, the gate structure 306 can be interchangeable referred to as a gate pattern, a gate feature, a gate line, a gate strip, or a gate.

In some embodiments, the gate dielectric layer 308 may include high-k dielectric. Examples of high-k dielectric material include HfO₂, HfSiO, HfSiON, HfTₐO, HfTiO, HfZrO, zirconium oxide, aluminum oxide, titanium oxide, hafnium dioxide-alumina (HfO₂—Al₂O₃) alloy, other suitable high-k dielectric materials, and/or combinations thereof. In some embodiments, a dielectric constant of the gate dielectric layer 308 can be greater than a dielectric constant of the gate spacer 92. In some embodiments, the gate electrode layer 310 may include work function metal layer(s) and a filling metal. The work function metal layer may be an n-type or p-type work function layer. Exemplary p-type work function metals include TiN, TaN, Ru, Mo, Al, WN, ZrSi₂, MoSi₂, TaSi₂, NiSi₂, WN, other suitable p-type work function materials, or combinations thereof. Exemplary n-type work function metals include Ti, Ag, TaAl, TaAlC, TiAlN, TaC, TaCN, TaSiN, Mn, Zr, other suitable n-type work function materials, or combinations thereof. The work function layer may include a plurality of layers. The filling metal may include tungsten (W), aluminum (Al), copper (Cu), or another suitable conductive material(s).

An etch back process can be performed on the gate electrode layer 310 and the gate dielectric layer 308 to scale down the gate structure 306. The etch back process may include a bias plasma etching step. The bias plasma etching step may be performed to remove portions of the gate electrode layer 310 and the gate dielectric layer 308. Portions of the gate trench GT may reappear with shallower depth. Top surfaces of the gate electrode layer 310 and the gate dielectric layer 308 may be no longer level with the ILD layer 104. Inner sidewalls of the gate spacers 92 are then exposed from the gate electrode layer 310 and the gate dielectric layer 308. In some embodiments, the bias plasma etching step may use a gas mixture of Cl₂, O₂, BCl₃, and Ar with a bias in a range from about 25V to about 1200V.

Subsequently, a hard mask layer 312 can be formed over the gate electrode layer 310 and the gate dielectric layer 308 using, for example, a deposition process to deposit a dielectric material over the substrate 50, followed by a CMP process to remove excess dielectric material above the gate spacers 92 and the ILD layer 104. In some embodiments, source/drain contacts 106 (see FIGS. 10A-10C) formed subsequently are formed by a self-aligned contact process using the hard mask layer 312 as a contact etch protection layer. In some embodiments, the hard mask layer 312 may be made of a nitride-based material, such as Si₃N₄, SiON, or a carbon-based material, such as SiC, SiOC, SiOCN, or combinations thereof. In some embodiments, the hard mask layer 312 may include SiOₓ, SiBN, SiCBN, other suitable dielectric materials, or combinations thereof. In some embodiments, the hard mask layer 312 may include a metal oxide, such as be hafnium oxide (HfO₂), zirconium oxide (ZrO₂), lanthanum oxide (La₂O₃), yttrium oxide (Y₂O₃), aluminum oxide (Al₂O₃), tantalum oxide (Ta₂O₅), titanium oxide (TiO₂), another applicable material, or combinations thereof. The hard mask layer 312 has different etch selectivity than the gate spacers 92 and/or the ILD layer 104, so as to selective etch back the hard mask layer 312. By way of example, if the hard mask layer 312 is made of silicon nitride, the gate spacers 92 and/or the ILD layer 104 may be made of a dielectric material different from silicon nitride. Therefore, the hard mask layer 312 can be used to define self-aligned gate contact region and thus referred to as a self-aligned contact (SAC) structure or a SAC layer.

In some embodiments, the dielectric regions 314 (see FIG. 9A) can be formed on opposite ends of the gate electrode layer 310 after the forming of the hard mask layer 312. In some embodiments, each dielectric region 314 is a gate-cut structure for the gate structure. In some embodiments, the dielectric region 314 can be interchangeably referred to a gate end dielectric. Specifically, the opposite ends the gate electrode layers 310 can be removed to form gate trenches. The ends of the gate electrode layers 310 may be removed by dry etching, wet etching, or a combination of dry and wet etching. Subsequently, a dielectric material is deposited into the gate trenches, followed by a planarization process to remove excess portions of the dielectric material. The remaining dielectric material forms the dielectric regions 314.

In some embodiments, the deposition of the dielectric material of the dielectric regions 314 can be performed using a conformal deposition process such as ALD, which may be PEALD, thermal ALD, or the like. The dielectric material may be formed of or comprise SiO₂, SiOC, SiOCN, or the like, or combinations thereof. In some embodiments, the dielectric region 314 may be made of a nitride-based material, such as Si₃N₄, or a carbon-based material, such as SiOCN, or combinations thereof. In some embodiments, the dielectric region 314 may be made of a material having a dielectric constant greater than about 9 (e.g., high dielectric constant (high-k) material). For example, the dielectric region 314 may be made of a high dielectric constant (high-k) material, such as be hafnium oxide (HfO₂), zirconium oxide (ZrO₂), lanthanum oxide (La₂O₃), yttrium oxide (Y₂O₃), aluminum oxide (Al₂O₃), tantalum oxide (Ta₂O₅), titanium oxide (TiO₂), another applicable material, or combinations thereof. The dielectric regions 314 may be formed of a homogenous material, or may have a composite structure including more than one layer. The dielectric regions 314 may include dielectric liners, which may be formed of, for example, silicon oxide. In some embodiments, the dielectric material of the dielectric regions 314 comprises SiN, and the deposition is performed using process gases including dichlorosilane and ammonia. Hydrogen (H₂) may or may not be added.

Reference is made to FIGS. 10A-10C. Source/drain contacts 106 (see FIGS. 10B and 10C) can be formed in the ILD layer 104 and over the source/drain structures 100. In some embodiments, materials of the source/drain contacts 106 may include Cu, Co, Ru, Pt, Al, W, Ti, TaN, TiN, Molybdenum (Mo), Ruthenium (Ru), Iridium (Ir), rhodium (Rh), or any combinations thereof. In some embodiments, the electrical conductivity of the source/drain contact 106 can be greater than the electrical conductivity of the source/drain structure 100. In some embodiments, an electrical conductivity of the source/drain contact 106 can be greater than an electrical conductivity of the source/drain structure 100. In some embodiments, the source/drain contact 106 can be interchangeably referred to a contact feature, a conductive feature, or a metal contact.

In some embodiments, silicide layers 107 (see FIGS. 10B and 10C) can be formed over the source/drain structures 100. Specifically, a metal silicidation process can be performed on the source/drain structure 100 to form the silicide layer 107. The metal silicidation process is to make a reaction between metal and silicon (or polycrystalline silicon). In some embodiments, a metal layer is formed on the source/drain structure 100. Subsequently, regarding the metal silicidation process, a first rapid thermal annealing (RTA) process may be performed in, for example, Ar, He, N₂ or other inert atmosphere at a first temperature, such as lower than 200~300° C., to convert the deposited metal layer into metal silicide. This is followed by an etching process to remove the unreacted metal layer from. The etching process may include a wet etch, a dry etch, and/or a combination thereof. As an example, the etchant of the wet etching may include a mixed solution of H₂SO₄, H₂O₂, H₂O, and/or other suitable wet etching solutions, and/or combinations thereof. Then, a second annealing or RTA step at a second temperature higher than the first temperature, such as 400~500° C., thereby forming the silicide layer 107 with low resistance. In some embodiments, the silicide layer 107 may include titanium silicide (TiSi), nickel silicide (NiSi), cobalt silicide (CoSi), Ni-Pt, or combinations thereof. In some embodiments, an electrical conductivity of the silicide layer 107 can be between an electrical conductivity of the source/drain structure 100 and an electrical conductivity of the source/drain contact 106.

An ILD layer 108 is deposited over the ILD layer 104. Subsequently, source/drain vias 116 (see FIGS. 10B and 10C) are formed in the ILD layer 108 and land on the source/drain contacts 106. Gate vias 316 (see FIG. 10A) are formed to pass through the ILD layer 108 and the hard mask layer 312 and land on the gate electrode layer 310. The source/drain vias 116 and/or the gate vias 316 may include a metal-containing material such as titanium nitride, titanium oxide, tungsten, cobalt, ruthenium, aluminum, copper, combinations thereof, multi-layers thereof, or the like. The ILD layer 108 may be made of an oxide, such as silicon oxide, a nitride, such as silicon nitride, the like, or a combination thereof, which may be formed by a chemical vapor deposition (CVD) process, such as high density plasma CVD (HDP-CVD), flowable chemical vapor deposition (FCVD), the like, or a combination thereof.

Subsequently, a front-side interconnect structure can be formed over the front-side gate vias 316 and the front-side source/drain vias 116. The interconnect structure includes a plurality of metallization layers with a plurality of metallization vias or interconnects. Other embodiments may contain more or fewer metallization layers and corresponding more or fewer number of vias. The metal line illustrated here just for an example, and the metal line may be otherwise oriented (rotated 90 degrees or at other orientations). The front-side interconnect structure may include metal layer 230 (e.g., Metal-0 (M0) layer) include several M0 tracks for power (e.g., power rails VDD and VSS) and signal routing (e.g., M0 tracks #1 to #5).

The tracks can be formed in an IMD (inter-metal dielectric) layer 118. The tracks can be electrically connected to the gate electrode layers 310 through the gate vias 316 and electrically connected to the source/drain structures 100 through the source/drain vias 116 and the source/drain contacts 106. In some embodiments, materials of the track may include Cu, Co, Ru, Pt, Al, W, Ti, TaN, TiN, Molybdenum (Mo), Ruthenium (Ru), Iridium (Ir), rhodium (Rh), or any combinations thereof. In some embodiments, the IMD layer 118 may be formed of an oxide such as Phospho-Silicate Glass (PSG), Boro-Silicate Glass (BSG), Boron-Doped Phospho-Silicate Glass (BPSG), Tetra Ethyl Ortho Silicate (TEOS) oxide, or the like. In some embodiments, the dielectric constant of the gate dielectric layer 308 of the transistor can greater than the dielectric constant of at least one of the ILD layer 108 and/or the IMD layer 118. In some embodiments, the source/drain via 116 can be interchangeably referred to a via feature, a conductive feature, or a metal via.

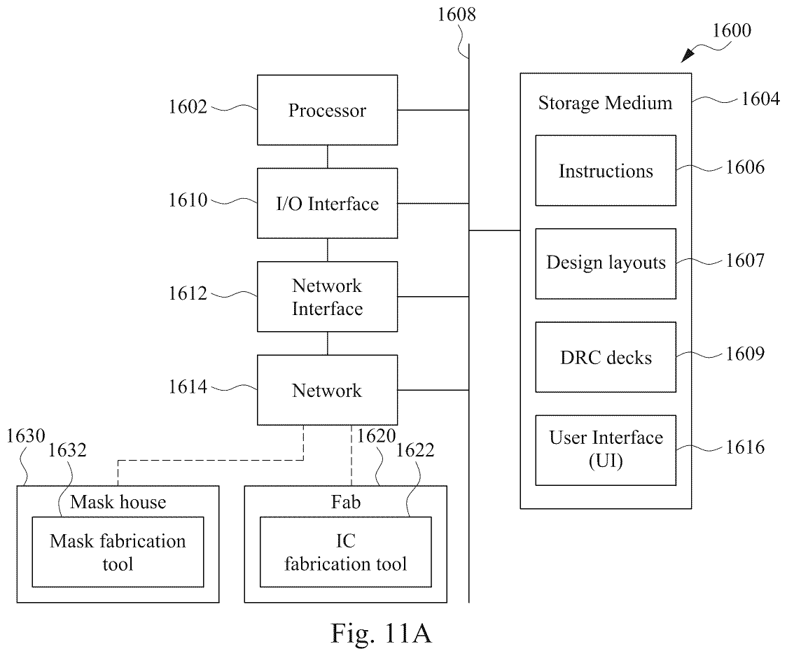

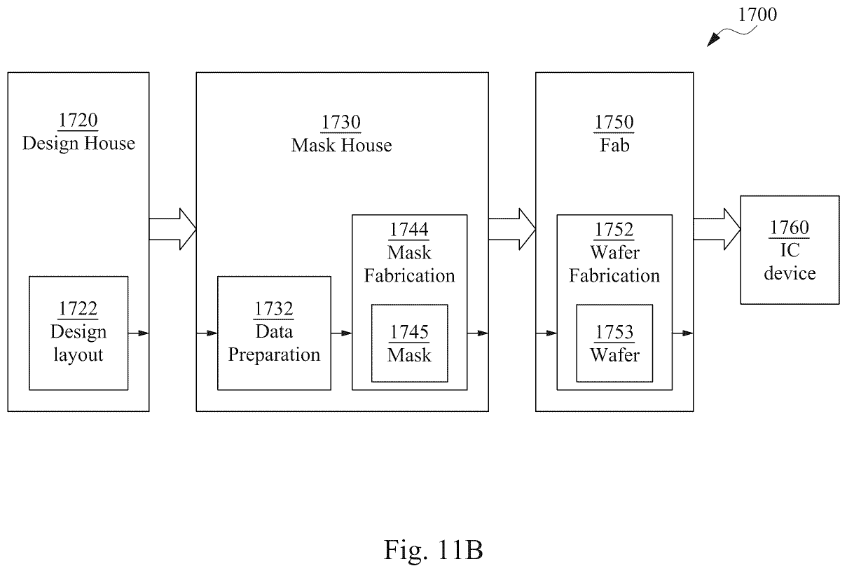

Reference is made to FIG. 11A. FIG. 11A is a schematic diagram of an electronic design automation (EDA) system 1600, in accordance with some embodiments. Methods described herein of generating design layouts, e.g., layouts of the integrated circuits of the semiconductor structure as discussed above, in accordance with one or more embodiments, are implementable, for example, using EDA system 1600, in accordance with some embodiments. At least integrated circuit is manufactured by a corresponding layout design similar to the corresponding integrated circuit. For brevity FIGS. 1B-10C are described as corresponding integrated circuits, but in some embodiments, FIGS. 1B-10C also correspond to layout designs with corresponding patterns with corresponding structures, and pattern relationships including alignment, lengths and widths, as well as configurations and layers of a corresponding layout design are similar to the structural relationships and configurations and layers of the corresponding integrated circuit, and similar detailed description will not be described for brevity. In some embodiments, EDA system 1600 is a computing device that is capable of executing one or more automatic placement & routing (APR) operations. The EDA system 1600 including a hardware processor 1602 and a non-transitory, computer-readable storage medium 1604. Computer-readable storage medium 1604, amongst other things, is encoded with, i.e., stores, a set of executable instructions 1606, design layouts 1607, design rule check (DRC) decks 1609 or any intermediate data for executing the set of instructions. Each design layout 1607 may include a graphical representation of an integrated chip, such as for example, a GSII file. Each DRC deck 1609 may include a list of design rules specific to a semiconductor process chosen for fabrication of a design layout 1607. Execution of instructions 1606, design layouts 1607 and DRC decks 1609 by hardware processor 1602 represents (at least in part) an EDA tool which implements a portion or all of, e.g., the methods described herein in accordance with one or more (hereinafter, the noted processes and/or methods).

Processor 1602 is electrically coupled to computer-readable storage medium 1604 via a bus 1608. Processor 1602 is also electrically coupled to an I/O interface 1610 by bus 1608. A network interface 1612 is also electrically connected to processor 1602 via bus 1608. Network interface 1612 is connected to a network 1614, so that processor 1602 and computer-readable storage medium 1604 are capable of connecting to external elements via network 1614. Processor 1602 is configured to execute instructions 1606 encoded in computer-readable storage medium 1604 in order to cause EDA system 1600 to be usable for performing a portion or all of the noted processes and/or methods. In one or more embodiments, processor 1602 is a central processing unit (CPU), a multi-processor, a distributed processing system, an application specific integrated circuit (ASIC), and/or a suitable processing unit.

In one or more embodiments, computer-readable storage medium 1604 is an electronic, magnetic, optical, electromagnetic, infrared, and/or a semiconductor system (or apparatus or device). For example, computer-readable storage medium 1604 includes a semiconductor or solid-state memory, a magnetic tape, a removable computer diskette, a random access memory (RAM), a read-only memory (ROM), a rigid magnetic disk, and/or an optical disk. In one or more embodiments using optical disks, computer-readable storage medium 1604 includes a compact disk-read only memory (CD-ROM), a compact disk-read/write (CD-R/W), and/or a digital video disc (DVD).

In one or more embodiments, computer-readable storage medium 1604 stores instructions 1606, design layouts 1607 (e.g., layouts of the integrated circuits of the semiconductor structure as discussed previously) and DRC decks 1609 configured to cause EDA system 1600 (where such execution represents (at least in part) the EDA tool) to be usable for performing a portion or all of the noted processes and/or methods. In one or more embodiments, storage medium 1604 also stores information which facilitates performing a portion or all of the noted processes and/or methods.

EDA system 1600 includes I/O interface 1610. I/O interface 1610 is coupled to external circuitry. In one or more embodiments, I/O interface 1610 includes a keyboard, keypad, mouse, trackball, trackpad, touchscreen, and/or cursor direction keys for communicating information and commands to processor 1602.

EDA system 1600 also includes network interface 1612 coupled to processor 1602. Network interface 1612 allows EDA system 1600 to communicate with network 1614, to which one or more other computer systems are connected. Network interface 1612 includes wireless network interfaces such as BLUETOOTH, WIFI, WIMAX, GPRS, or WCDMA; or wired network interfaces such as ETHERNET, USB, or IEEE-1388. In one or more embodiments, a portion or all of noted processes and/or methods, is implemented in two or more EDA systems 1600.

EDA system 1600 is configured to receive information through I/O interface 1610. The information received through I/O interface 1610 includes one or more of instructions, data, design rules, libraries of standard cells, and/or other parameters for processing by processor 1602. The information is transferred to processor 1602 via bus 1608. EDA system 1600 is configured to receive information related to a user interface (UI) 1616 through I/O interface 1610. The information is stored in computer-readable medium 1604 as UI 1616.

Also illustrated in FIG. 11A are fabrication tools associated with the EDA system 1600. For example, a mask house 1630 receives a design layout from the EDA system 1600 by, for example, the network 1614, and the mask house 1630 has a mask fabrication tool 1632 (e.g., a mask writer) for fabricating one or more photomasks (e.g., photomasks used for fabricating integrated circuits of the semiconductor structure as discussed above) based on the design layout generated from the EDA system 1600. An IC fabricator (“Fab”) 1620 may be connected to the mask house 1630 and the EDA system 1600 by, for example, the network 1614. Fab 1620 includes an IC fabrication tool 1622 for fabricating IC chips (e.g., layouts of the integrated circuits of the semiconductor structure with resistor circuits as discussed above) using the photomasks fabricated by the mask house 1630. By way of example and not limitation, the IC fabrication tool 1622 includes one or more cluster tools for fabricating IC chips. The cluster tool may be a multiple reaction chamber type composite equipment which includes a polyhedral transfer chamber with a wafer handling robot inserted at the center thereof, a plurality of process chambers (e.g., CVD chamber, PVD chamber, etching chamber, annealing chamber or the like) positioned at each wall face of the polyhedral transfer chamber; and a loadlock chamber installed at a different wall face of the transfer chamber.

Reference is made to FIG. 11B. FIG. 11B is a block diagram of an IC manufacturing system 1700, and an IC manufacturing flow associated therewith, in accordance with some embodiments. In some embodiments, based on one or more design layouts, e.g., layouts of the integrated circuits of the semiconductor structure as discussed above, one or more photomasks and one or more integrated circuits are fabricated using manufacturing system 1700.

In FIG. 11B, an IC manufacturing system 1700 includes entities, such as a design house 1720, a mask house 1730, and a Fab 1750, that interact with one another in the design, development, and manufacturing cycles and/or services related to manufacturing ICs 1760. The entities in IC manufacturing system 1700 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 1720, mask house 1730, and Fab 1750 is owned by a single larger company. In some embodiments, two or more of design house 1720, mask house 1730, and Fab 1750 coexist in a common facility and use common resources.

Design house (or design team) 1720 generates design layouts 1722 (e.g., layouts of the integrated circuits of the semiconductor structure as discussed above). Design layouts 1722 include various geometrical patterns designed for ICs 1760 (e.g., integrated circuits of the semiconductor structure as discussed above). The geometrical patterns correspond to patterns of metal, oxide, or semiconductor layers that make up the various components of ICs 1760 to be fabricated. The various layers combine to form various device features. For example, a portion of design layout 1722 includes various circuit features, such as active regions, passive regions, functional gate structures, resistor structures, gate contacts, resistor contacts, source/drain contacts, and/or metal lines, to be formed on a semiconductor wafer. Design house 1720 implements a proper design procedure to form design layout 1722. The design procedure includes one or more of logic design, physical design or place and route. Design layout 1722 is presented in one or more data files having information of the geometrical patterns and a netlist of various nets. For example, design layout 1722 can be expressed in a GDSII file format or DFII file format.

Mask house 1730 includes data preparation 1732 and mask fabrication 1744. Mask house 1730 uses design layout 1722 (e.g., layout of the integrated circuit of the semiconductor structure as discussed above) to manufacture one or more photomasks 1745 to be used for fabricating the various layers of IC 1760 according to design layout 1722. Mask house 1730 performs mask data preparation 1732, where design layout 1722 is translated into a representative data file (“RDF”). Mask data preparation 1732 provides the RDF to mask fabrication 1744. Mask fabrication 1744 includes a mask writer. A mask writer converts the RDF to an image on a substrate, such as a photomask (reticle) 1745. Design layout 1722 is manipulated by mask data preparation 1732 to comply with particular characteristics of the mask writer and/or rules of fab 1750. In FIG. 11B, mask data preparation 1732 and mask fabrication 1744 are illustrated as separate elements. In some embodiments, mask data preparation 1732 and mask fabrication 1744 can be collectively referred to as mask data preparation.

In some embodiments, mask data preparation 1732 includes optical proximity correction (OPC) which uses lithography enhancement techniques to compensate for image errors, such as those that can arise from diffraction, interference, other process effects and the like. OPC adjusts design layout 1722. In some embodiments, mask data preparation 1732 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 1732 includes a mask rule checker (MRC) that checks design layout 1722 that has undergone processes in OPC with a set of mask creation rules which contain certain geometric and/or connectivity restrictions to ensure sufficient margins, to account for variability in semiconductor manufacturing processes, and the like. In some embodiments, the MRC modifies design layout 1722 diagram to compensate for limitations during mask fabrication 1744, which may undo part of the modifications performed by OPC in order to meet mask creation rules.

In some embodiments, mask data preparation 1732 includes lithography process checking (LPC) that simulates processing that will be implemented by Fab 1750 to fabricate ICs 1760. LPC simulates this processing based on design layout 1722 to create a simulated manufactured integrated circuit, such as IC 1760. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC are be repeated to further refine design layout 1722.

After mask data preparation 1732 and during mask fabrication 1744, a photomask 1745 or a group of photomasks 1745 are fabricated based on the design layout 1722. In some embodiments, mask fabrication 1744 includes performing one or more lithographic exposures based on the design layout 1722. In some embodiments, an electron-beam (e-beam) or a mechanism of multiple e-beams is used to form a pattern on a photomask 1745 based on design layout 1722. Photomask 1745 can be formed in various technologies. In some embodiments, photomask 1745 is formed using binary technology. In some embodiments, a mask pattern includes opaque regions and transparent regions. A radiation beam, such as an ultraviolet (UV) beam, used to expose the radiation sensitive material layer (e.g., photoresist) which has been coated on a wafer, is blocked by the opaque regions and transmits through the transparent regions. In one example, a binary mask version of photomask 1745 includes a transparent substrate (e.g., fused quartz) and an opaque material (e.g., chromium) coated in the opaque regions of the binary mask. In another example, photomask 1745 is formed using a phase shift technology. In a phase shift mask (PSM) version of photomask 1745, various features in the pattern formed on the phase shift photomask are configured to have proper phase difference to enhance the resolution and imaging quality. In various examples, the phase shift photomask can be attenuated PSM or alternating PSM. The photomask(s) generated by mask fabrication 1744 is used in a variety of processes. For example, such a mask(s) is used in an ion implantation process to form various doped regions in semiconductor wafer 1753, in an etching process to form various etching regions in semiconductor wafer 1753, and/or in other suitable processes.

Fab 1750 may include wafer fabrication 1752. Fab 1750 is an IC fabrication business that includes one or more manufacturing facilities for the fabrication of a variety of different IC products. In some embodiments, Fab 1750 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (BEOL fabrication), and a third manufacturing facility may provide other services for the foundry business.

Fab 1750 uses photomask(s) 1745 fabricated by mask house 1730 to fabricate ICs 1760. Thus, fab 1750 at least indirectly uses design layout(s) 1722 (e.g., layouts of the integrated circuits of the semiconductor structure as discussed above) to fabricate ICs 1760. In some embodiments, wafer 1753 is processed by fab 1750 using photomask(s) 1745 to form ICs 1760. In some embodiments, the device fabrication includes performing one or more photolithographic exposures based at least indirectly on design layout 1722.

Therefore, based on the above discussions, it can be seen that the present disclosure offers advantages. It is understood, however, that other embodiments may offer additional advantages, and not all advantages are necessarily disclosed herein, and that no particular advantage is required for all embodiments. The present disclosure in various embodiments provides a method to address the inefficiency in Metal-0 (M0) layout design for one-half-height (OHH) cells. Specifically, the width of M0 tracks from #1 to #5 (see FIG. 1C) can be increased, and thus the size of the via associated with the M0 layer can be expanded to reduce resistance (Rc). Additionally, a functionless (or redundant) M0 track (i.e., M0 track #6 track, not shown) can be removed. Furthermore, no additional mask is required for implementing this new layout. Therefore, these improvements can collectively enhance the electrical performance of the OHH cells by reducing Rc and enabling faster operational speeds.

In some embodiments, a method includes forming a first active region of a first circuit unit cell disposed over a substrate; forming a second active region of a second circuit unit cell disposed over the substrate, the second active region comprising a channel region and a source/drain region adjacent to the channel region, wherein in a top view, the second circuit unit cell has a greater cell height than the first circuit unit cell; forming a gate structure interfacing at least three surfaces of the channel region of the second active region, wherein the gate structure comprises a gate dielectric layer over the channel region and a gate electrode over the gate dielectric layer; forming an epitaxial feature disposed over the source/drain region of the second active region, the epitaxial feature being adjacent to a sidewall of the channel region of the second active region; forming a first interconnect structure disposed over the first circuit unit cell, the first interconnect structure comprising a plurality of first signal lines and a plurality of first power lines disposed in a first dielectric layer, wherein a dielectric constant of the gate dielectric layer is greater than a dielectric constant of the first dielectric layer; forming a second interconnect structure disposed over the second circuit unit cell, the second interconnect structure comprising a plurality of second signal lines and a plurality of second power lines disposed in the first dielectric layer, wherein a width of a first one of the second signal lines is greater than a width of a first one of the first signal lines.

In some embodiments, the cell height of the second circuit unit cell is 1.5 times the cell height of the first circuit unit cell. In some embodiments, the cell height of the second circuit unit cell less than twice the cell height of the first circuit unit cell. In some embodiments, the method further includes forming a metal contact over the epitaxial feature of the first active region; forming a metal via over the metal contact, wherein the first one of the second signal lines is formed over the metal via. In some embodiments, the first one and a second one of the second signal lines are positioned on opposing sides of one of the second power lines, and the width of the first one of the second signal lines is different from a width of the second one of the second signal lines. In some embodiments, the method further includes forming a metal via over the first one the second signal lines, wherein in the top view, the metal via has a greater dimension than the width of the first one of the first signal lines in the lengthwise direction of the gate structure. In some embodiments, a width of one the second power lines is substantially equal to a width of one of the first power lines. In some embodiments, there are three adjacent second power lines, referred to as first, second, and third ones of the second power lines, and a number of second signal lines located between the first and second ones of the second power lines is different from a number of second signal lines located between the second and third ones of the second power lines. In some embodiments, a number of second signal line located between two adjacent second power lines is less than a number of first signal line located between two adjacent first power lines. In some embodiments, the second active region has a wider width than the first active region.

In some embodiments, a method includes forming an active region of a circuit unit cell over a substrate, the active region comprising a channel region and a source/drain region adjacent to the channel region; forming a gate structure comprising a gate dielectric layer over the active region and a gate electrode over the gate dielectric layer; forming a gate spacer extending along a sidewall of the gate structure, wherein a dielectric constant of the gate dielectric layer is greater than a dielectric constant of the gate spacer; forming a source/drain feature disposed over the source/drain region of the active region; forming a first interlayer dielectric (ILD) layer disposed over the source/drain feature; forming a source/drain contact extending through the ILD layer to electrically couple to the source/drain feature, wherein an electrical conductivity of the source/drain contact is greater than an electrical conductivity of the source/drain feature; forming a second ILD layer over the source/drain contact; forming a plurality of signal lines and a plurality of power lines disposed in the second ILD layer, wherein there are three adjacent power lines, referred to as first, second, and third ones of the power lines, and a number of signal lines located between the first and second ones of the power lines is less than a number of signal lines located between the second and third ones of the power lines.

In some embodiments, footprints of the first and second ones of the power lines are located within the circuit unit cell, and a footprint of the third one of the power lines is located outside the circuit unit cell. In some embodiments, in a top view, the active region of the circuit unit cell has a greater width than the signal lines and the power lines in a lengthwise direction of the gate structure. In some embodiments, the method further includes forming a metal via over the source/drain contact, wherein one of the signal lines is formed over the metal via. In some embodiments, the circuit unit cell is configured as a logic circuit.

In some embodiments, a semiconductor structure includes a transistor, a first dielectric layer, a contact feature, a metal silicide layer, and an interconnect structure. The transistor of a circuit unit cell includes a gate structure interfacing at least three surfaces of a channel and an epitaxial source/drain feature interfacing a sidewall of the channel. The gate structure includes ca gate dielectric layer over the channel and a gate electrode over the gate dielectric layer. The first dielectric layer is disposed over the epitaxial source/drain feature. The contact feature extends through the first dielectric layer. The metal silicide layer is between the epitaxial source/drain feature and the contact feature, wherein the contact feature is surrounded by the first dielectric layer, wherein an electrical conductivity of the metal silicide layer is between an electrical conductivity of the epitaxial source/drain feature and an electrical conductivity of the contact feature. The interconnect structure disposed over the first dielectric layer, the interconnect structure comprising a plurality of metal power features and a plurality of metal signal features disposed in a second dielectric layer, wherein a dielectric constant of the gate dielectric layer is greater than a dielectric constant of the second dielectric layer, and a first one and a second one of the metal signal features are positioned on opposing sides of a first one of the metal power features, and in a top view, a width of the first one of the metal signal features is different from a width of the second one of the metal signal features.

In some embodiments, footprints of the first and second ones of the metal signal features and the first one of the metal power features are located within the circuit unit cell. In some embodiments, the semiconductor structure further includes a via feature disposed over the contact feature, wherein the first one of the metal signal features is formed over the via feature. In some embodiments, in the top view, the channel of the transistor has a greater width than the metal signal features in a lengthwise direction of the gate structure. In some embodiments, there are three adjacent metal power features, referred to as first, second, and third ones of the metal power features, and a number of metal signal features located between the first and second ones of the metal power features is less than a number of metal signal features located between the second and third ones of the metal power features.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a first active region of a first circuit unit cell disposed over a substrate;
forming a second active region of a second circuit unit cell disposed over the substrate, the second active region comprising a channel region and a source/drain region adjacent to the channel region, wherein in a top view, the second circuit unit cell has a greater cell height than the first circuit unit cell;
forming a gate structure interfacing at least three surfaces of the channel region of the second active region, wherein the gate structure comprises a gate dielectric layer over the channel region and a gate electrode over the gate dielectric layer;
forming an epitaxial feature disposed over the source/drain region of the second active region, the epitaxial feature being adjacent to a sidewall of the channel region of the second active region;
forming a first interconnect structure disposed over the first circuit unit cell, the first interconnect structure comprising a plurality of first signal lines and a plurality of first power lines disposed in a first dielectric layer, wherein a dielectric constant of the gate dielectric layer is greater than a dielectric constant of the first dielectric layer; and
forming a second interconnect structure disposed over the second circuit unit cell, the second interconnect structure comprising a plurality of second signal lines and a plurality of second power lines disposed in the first dielectric layer, wherein a width of a first one of the second signal lines is greater than a width of a first one of the first signal lines.

2. The method of claim 1, wherein the cell height of the second circuit unit cell is 1.5 times the cell height of the first circuit unit cell.

3. The method of claim 1, wherein the cell height of the second circuit unit cell less than twice the cell height of the first circuit unit cell.

4. The method of claim 1, further comprising:
forming a metal contact over the epitaxial feature of the first active region; and
forming a metal via over the metal contact, wherein the first one of the second signal lines is formed over the metal via.

5. The method of claim 1, wherein the first one and a second one of the second signal lines are positioned on opposing sides of one of the second power lines, and the width of the first one of the second signal lines is different from a width of the second one of the second signal lines.

6. The method of claim 1, further comprising:
forming a metal via over the first one the second signal lines, wherein in the top view, the metal via has a greater dimension than the width of the first one of the first signal lines in the lengthwise direction of the gate structure.

7. The method of claim 1, wherein a width of one the second power lines is substantially equal to a width of one of the first power lines.

8. The method of claim 1, wherein there are three adjacent second power lines, referred to as first, second, and third ones of the second power lines, and a number of second signal lines located between the first and second ones of the second power lines is different from a number of second signal lines located between the second and third ones of the second power lines.

9. The method of claim 1, wherein a number of second signal line located between two adjacent second power lines is less than a number of first signal line located between two adjacent first power lines.

10. The method of claim 1, wherein the second active region has a wider width than the first active region.

11. A method, comprising:
forming an active region of a circuit unit cell over a substrate, the active region comprising a channel region and a source/drain region adjacent to the channel region;
forming a gate structure comprising a gate dielectric layer over the active region and a gate electrode over the gate dielectric layer;
forming a gate spacer extending along a sidewall of the gate structure, wherein a dielectric constant of the gate dielectric layer is greater than a dielectric constant of the gate spacer;
forming a source/drain feature disposed over the source/drain region of the active region;
forming a first interlayer dielectric (ILD) layer disposed over the source/drain feature;
forming a source/drain contact extending through the ILD layer to electrically couple to the source/drain feature, wherein an electrical conductivity of the source/drain contact is greater than an electrical conductivity of the source/drain feature;
forming a second ILD layer over the source/drain contact; and
forming a plurality of signal lines and a plurality of power lines disposed in the second ILD layer, wherein there are three adjacent power lines, referred to as first, second, and third ones of the power lines, and a number of signal lines located between the first and second ones of the power lines is less than a number of signal lines located between the second and third ones of the power lines.

12. The method of claim 11, wherein footprints of the first and second ones of the power lines are located within the circuit unit cell, and a footprint of the third one of the power lines is located outside the circuit unit cell.

13. The method of claim 11, wherein in a top view, the active region of the circuit unit cell has a greater width than the signal lines and the power lines in a lengthwise direction of the gate structure.

14. The method of claim 11, further comprising:
forming a metal via over the source/drain contact, wherein one of the signal lines is formed over the metal via.

15. The method of claim 11, wherein the circuit unit cell is configured as a logic circuit.

16. A semiconductor structure, comprising:
a transistor of a circuit unit cell comprising a gate structure interfacing at least three surfaces of a channel and an epitaxial source/drain feature interfacing a sidewall of the channel, wherein the gate structure comprises a gate dielectric layer over the channel and a gate electrode over the gate dielectric layer;
a first dielectric layer disposed over the epitaxial source/drain feature;
a contact feature extending through the first dielectric layer;
a metal silicide layer between the epitaxial source/drain feature and the contact feature, wherein the contact feature is surrounded by the first dielectric layer, wherein an electrical conductivity of the metal silicide layer is between an electrical conductivity of the epitaxial source/drain feature and an electrical conductivity of the contact feature; and
an interconnect structure disposed over the first dielectric layer, the interconnect structure comprising a plurality of metal power features and a plurality of metal signal features disposed in a second dielectric layer, wherein a dielectric constant of the gate dielectric layer is greater than a dielectric constant of the second dielectric layer, and a first one and a second one of the metal signal features are positioned on opposing sides of a first one of the metal power features, and in a top view, a width of the first one of the metal signal features is different from a width of the second one of the metal signal features.

17. The semiconductor structure of claim 16, wherein footprints of the first and second ones of the metal signal features and the first one of the metal power features are located within the circuit unit cell.

18. The semiconductor structure of claim 16, further comprising:
a via feature disposed over the contact feature, wherein the first one of the metal signal features is formed over the via feature.

19. The semiconductor structure of claim 16, wherein in the top view, the channel of the transistor has a greater width than the metal signal features in a lengthwise direction of the gate structure.

20. The semiconductor structure of claim 16, wherein there are three adjacent metal power features, referred to as first, second, and third ones of the metal power features, and a number of metal signal features located between the first and second ones of the metal power features is less than a number of metal signal features located between the second and third ones of the metal power features.
